(19) United States
(12) Patent Application Publication
(10) Pub. No.: US 2007/0155138 A1
(43) Pub. Date: Jul. 5, 2007

(54) Apparatus and method for depositing silicon germanium films

(76) Inventors: Pierre Tomasini, Tempe, AZ (US); Matthias Bauer, Phoenix, AZ (US); Nyles W. Cody, Tempe, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/439,688

(22) Filed: May 23, 2006

Related U.S. Application Data
(60) Provisional application No. 60/684,435, filed on May 24, 2005.

(51) Int. Cl. H01L 21/20; H01L 21/36; H01L 31/20

(52) U.S. Cl. 438/483

(57) ABSTRACT

A new model is provided for the CVD growth of silicon germanium from silicon-containing and germanium-containing precursors. According to the new model, the germanium concentration x is related to the gas phase ratio according to the equation [x/(1−x)]²=mP_{Ge}/P_{Si}, and m=Ae^{-E/(RT)}, where P_{Si} is the partial pressure of the silicon-containing precursor, P_{Ge} is the partial pressure of the germanium-containing precursor, A is a constant, R is the universal gas constant, and T is the temperature. Methods and apparatuses are described for controlling CVD process parameters, associated with a series of reactions at constant or varied temperature, to achieve targeted germanium concentrations in silicon germanium films deposited onto semiconductor substrates. In particular, the new model can be used to calculate the resultant germanium concentration for selected precursor flow rates. The new model can also be used to control a precursor injection apparatus to achieve a desired germanium concentration.

### CLAIM FOR PRIORITY

This application claims priority under 35 U.S.C. § 119(e) to Provisional Application No. 60/684,435, filed May 24, 2005.

### INCORPORATION BY REFERENCE

This application incorporates by reference the full disclosures of U.S. Pat. No. 5,221,556 to Hawkins et al. and U.S. Pat. No. 6,093,252 issued to Wengert et al.

### BACKGROUND OF THE INVENTION

1. Field of the Invention

The present invention relates generally to semiconductor processing and specifically to systems and methods for depositing silicon germanium films.

2. Description of the Related Art

A variety of methods are used in the semiconductor manufacturing industry to deposit materials onto surfaces. One widely used method is chemical vapor deposition (“CVD”), in which atoms or molecules contained in vapors are deposited onto a surface and built up to form a film. Typically, the film is deposited onto a surface of a substrate, such as a semiconductor wafer, contained within a reaction chamber. Some deposition processes involve the simultaneous injection of multiple reactant vapors (also referred to herein as “precursors”) that react with one another to deposit a film onto the substrate. Multiple deposition steps can be sequenced to produce devices with several layers. A film can be formed in a selective deposition process or in a blanket deposition process. In selective deposition, the film is deposited over certain areas of a substrate, whereas in blanket deposition, the film is deposited over substantially the entire substrate.

In a CVD process, the rate at which the film grows depends on whether the temperature is within a “mass transport limited regime” or a “kinetic regime” associated with the particular precursors involved in the chemical reaction. When the temperature is within the mass transport limited regime, the deposition rate depends primarily upon the mass flow rates of the precursor vapors. In the mass transport limited regime, the deposition rate is substantially independent of the temperature. When the temperature is within the kinetic regime, however, the deposition rate varies with the temperature at which the reaction takes place. Typically, the temperature range of the kinetic regime is lower than that of the mass transport limited regime.

Silicon germanium (SiGe) films have utility as base layers in heterojunction bipolar transistors (HBT), resistors in BiCMOS devices, and as gate electrodes in CMOS devices and various other integrated electronic devices. SiGe films can be deposited onto substrates using a CVD process in which silicon (Si) and germanium (Ge) are delivered to a surface where they react and form a SiGe film. SiGe films formed using CVD processes can have various morphologies, including single crystalline, polycrystalline, and amorphous morphologies. In epitaxial deposition of a SiGe film, the crystalline structure and morphology of the deposited film follows the crystalline structure of the underlying material onto which the epitaxial deposition occurs. In polycrystalline deposition, the deposited film has a grain structure that is different than that of the underlying material.

SiGe films can be formed by the reaction of precursors silane (SiₙH₂ₙ₊₂) and germane (GeₘH₂ₘ₊₂). Typical silane gases include monosilane (SiH₄), disilane (Si₂H₆), and trisilane (Si₃H₈). Typical germane gases include monogermane (GeH₄), digermane (Ge₂H₆), and trigermane (Ge₃H₈). SiGe films can also be formed by the reaction of a chlorosilane precursor with germane gas. Examples of chlorosilanes are dichlorosilane (SiH₂Cl₂) and trichlorosilane (SiHCl₃H), which are commonly referred to as “DCS” and “TCS,” respectively. An SiGe film is formed on a substrate contained within a reaction chamber by injecting both precursor gases into the chamber, typically with a carrier gas such as hydrogen gas (H₂), at an appropriate temperature and overall pressure.

A SiGe film can be said to have a composition Si₁₋ₓGeₓ, where x is the concentration of germanium (Ge) in the film. The germanium concentration x can be measured by X-ray diffraction (XRD), secondary ion math spectra (SIMS), or spectroscopic ellipsometry. The germanium concentration x is significant because, among other reasons, it affects the lattice size of a strained silicon layer (i.e., a silicon layer formed on a silicon germanium buffer layer), which in turn affects conductivity. Thus, the dependence of the germanium concentration x on processing conditions has been investigated. For SiGe films formed from precursors SiH₄ and GeH₄ at a steady state temperature and pressure, a generally accepted relationship between the germanium concentration x and the partial pressures of the precursors is

$$\frac{x}{1 - x} = m \frac{{P}_{{GeH}_{4}}}{{P}_{{SiH}_{4}}} \qquad ( 1 )$$

where P_{SiH4} and P_{GeH4} are the partial pressures of the monosilane and monogermane gases, respectively. The ratio of the partial pressures of the precursors (in this case the ratio P_{GeH4}/P_{SiH4}) is sometimes referred to as the “gas phase ratio.” While the term m is often referred to as the “proportionality constant” or “distribution coefficient,” it is understood to vary with temperature and total pressure. Equation 1 has been extrapolated from experimental data obtained from ultra high vacuum chemical vapor deposition (UHVCVD) reactors. When the reaction takes place within a CVD reaction chamber, wherein SiH₄ gas is injected at a flow rate F_{Si} and GeH₄ gas is injected at a flow rate F_{Ge}, it is understood that the ratio of the partial pressures P_{GeH4}/P_{SiH4} is equal to, and can conveniently be replaced in the equation by, the ratio of flow rates F_{Ge}/F_{Si}.

For Si₁₋ₓGeₓ films formed from precursors SiH₂Cl₂ (DCS) and GeH₄ at steady state temperature and pressure, the relationship between the germanium concentration x and the partial pressures of the precursors has been found to be

$$\frac{{x}^{2}}{1 - x} = m \frac{{P}_{{GeH}_{4}}}{{P}_{DCS}} . \qquad ( 2 )$$

As mentioned above, in the kinetic regime the rate of a chemical reaction depends upon the temperature at which the reaction occurs. Generally, the higher the temperature, the faster a given chemical reaction will proceed. Quantitatively, this relationship between the temperature and the rate at which a reaction proceeds is determined by the Arrhenius Equation. At higher temperatures, the probability that two molecules will collide is higher. This higher collision rate results in a higher kinetic energy, which has an effect on the activation energy of the reaction. The activation energy is the amount of energy required to ensure that a reaction occurs. The Arrhenius Equation is

$$k = A {ⅇ}^{- \frac{E}{RT}} \qquad ( 3 )$$

where k is the rate coefficient, A is a constant, E is the activation energy, R is the universal gas constant, and T is the temperature (in degrees Kelvin). R has the value of 8.314×10⁻³ kJ mol⁻¹K⁻¹. An Arrhenius plot is a plot of the natural log of k versus 1/T, which have a linear relationship with one another:

$$ln ( k ) = ln ( A ) - ( \frac{E}{R} ) ( \frac{1}{T} ) \qquad ( 4 )$$

### SUMMARY OF THE INVENTION

The inventors have discovered a new model for the CVD growth of silicon germanium from silane and germane precursor gases. Preferred embodiments provide methods and apparatus for controlling CVD process parameters to achieve targeted germanium concentrations in silicon germanium films. The new model can be used to calculate the resultant germanium concentration for selected process parameters. The new model can also be used to control precursor injection apparatus to achieve a desired germanium concentration.

In one aspect, the invention provides a method of depositing a silicon germanium layer with a targeted composition onto a substrate. The method involves injecting a silicon-containing precursor gas at a flow rate F_{1Si} and a germanium-containing precursor gas at a flow rate F_{1Ge} into a reaction chamber toward a substrate at a selected processing temperature with the chamber at a selected processing pressure. The precursor gases react to deposit a first silicon germanium layer with composition Si₁₋ₓGeₓ onto the substrate. The term x is measured. The method further involves injecting a silicon-containing precursor gas at a flow rate F_{2Si} and a germanium-containing precursor gas at a flow rate F_{2Ge} into the reaction chamber toward a substrate at the selected processing temperature with the chamber at the selected processing pressure. The precursor gases react to deposit a second silicon germanium layer with composition Si_{1-y}Ge_{y} onto the substrate, wherein y is a targeted value. The ratio F_{2Si}/F_{2Ge} substantially satisfies the equation

$$\frac{{F}_{2 Si}}{{F}_{2 Ge}} = {( \frac{x}{1 - x} )}^{2} {( \frac{1 - y}{y} )}^{2} ( \frac{{F}_{1 Si}}{{F}_{1 Ge}} ) .$$

In another aspect, the invention provides a method of depositing a silicon germanium layer with a targeted composition onto a substrate. A first substrate is provided at a selected processing temperature in a reaction chamber at a selected processing pressure. The method involves injecting SiH₄ gas at a flow rate F_{1Si} and GeH₄ gas at a flow rate F_{1Ge} into the reaction chamber toward the first substrate. The SiH₄ and GeH₄ gases react to deposit silicon germanium with composition Si₁₋ₓGeₓ onto the first substrate. The value of x is measured. A second substrate is provided at the selected processing temperature in the reaction chamber at the selected processing pressure. The method further involves injecting SiH₄ gas at a flow rate F_{2Si} and GeH₄ gas at a flow rate F_{2Ge} into the reaction chamber toward the second substrate, wherein the ratio F_{2Si}/F_{2Ge} substantially satisfies the equation

$$\frac{{F}_{2 Si}}{{F}_{2 Ge}} = {( \frac{x}{1 - x} )}^{2} {( \frac{1 - y}{y} )}^{2} ( \frac{{F}_{1 Si}}{{F}_{1 Ge}} )$$

and wherein y is a targeted value of a composition Si_{1-y}Ge_{y} of a silicon germanium layer deposited onto the second substrate by a reaction of the SiH₄ and GeH₄ gases.

In another aspect, the invention provides a method of calculating a parameter associated with a deposition process of a silicon germanium layer. A substrate is provided in a reaction chamber. A silane gas with a molecular formula SiₙH₂ₙ₊₂ is injected at a flow rate F_{1Si} and a mixture of a germane gas and a carrier gas is injected at a flow rate F_{1Gm} into the reaction chamber toward the substrate. The germane gas has a molecular formula GeₘH₂ₘ₊₂, and the mixture has a dilution d₁. The terms n and m are whole numbers. The silane and germane gases react to deposit silicon germanium with composition Si₁₋ₓGeₓ onto the substrate. The value of x is measured. Two parameters are selected from the set comprising (1) a flow rate F_{2Si} of a silane gas with a molecular formula SiₙH₂ₙ₊₂, (2) a flow rate F_{2Gm} of a mixture of a carrier gas and a germane gas with a molecular formula GeₘH₂ₘ₊₂ and dilution d₂, and (3) a concentration y in a silicon germanium composition Si_{1-y}Ge_{y}. Values are assigned to the two selected parameters, and the unselected parameter of said set is calculated from the equation

$$\frac{{F}_{2 Si}}{{F}_{2 Gm}} = {( \frac{x}{1 - x} )}^{2} {( \frac{1 - y}{y} )}^{2} ( \frac{{d}_{2}}{{d}_{1}} ) ( \frac{{F}_{1 Si}}{{F}_{1 Gm}} )$$

or from one or more equations that are collectively mathematically equivalent to the above equation.

In another aspect, the invention provides a method of depositing a silicon germanium film with a targeted composition onto a substrate. The method involves injecting SiH₄ gas at a flow rate F_{1Si} and GeH₄ gas at a flow rate F_{1Ge} into the reaction chamber toward a substrate at a first temperature T₁ (in Kelvin), wherein the SiH₄ and GeH₄ gases react to deposit a first silicon germanium film with composition Si₁₋ₓGeₓ onto the substrate. The value of x is measured. The method further involves injecting SiH₄ gas at a flow rate F_{2Si} and GeH₄ gas at a flow rate F_{2Ge} into the reaction chamber toward a substrate at a second temperature T₂ (in Kelvin), wherein the SiH₄ and GeH₄ gases react to deposit a second silicon germanium film with composition Si_{1-y}Ge_{y} onto the substrate. The value of y is measured. The method further involves injecting SiH₄ gas at a flow rate F_{3Si} and GeH₄ gas at a flow rate F_{3Ge} into the reaction chamber toward a substrate at a third temperature T3 (in Kelvin), wherein the ratio F_{3Si}/F_{3Ge} substantially satisfies the equation

$$\frac{{F}_{3 Si}}{{F}_{3 Ge}} = {( \frac{1 - z}{z} )}^{2} {( \frac{x}{1 - x} )}^{2} ( \frac{{F}_{1 Si}}{{F}_{1 Ge}} ) {ⅇ}^{( \frac{E}{R} ) ( \frac{1}{{T}_{1}} - \frac{1}{{T}_{3}} )}$$

The term z is a targeted value of a composition Si_{1-z}Ge_{z} of a third silicon germanium film deposited onto a substrate at a temperature T₃ (in Kelvin) by a reaction of SiH₄ and GeH₄ gases, wherein

$$\frac{E}{R} = \frac{ln [ {( \frac{1 - x}{x} )}^{2} ( \frac{{F}_{1 Ge}}{{F}_{1 Si}} ) ( \frac{{F}_{2 Si}}{{F}_{2 Ge}} ) ]}{\frac{1}{{T}_{1}} - \frac{1}{{T}_{2}}} .$$

In another aspect, the invention provides a method of calculating a parameter associated with a deposition process of a silicon germanium film. The method involves injecting silane gas at a flow rate F_{1Si} and a mixture of a carrier gas and germane gas with a dilution d₁ at a flow rate F_{1Gm} into a reaction chamber toward a substrate at a first temperature T₁ (in Kelvin), wherein the silane and germane gases react to deposit a first silicon germanium film with composition Si₁₋ₓGeₓ onto the substrate. The silane and germane gases have molecular formulas SiₙH₂ₙ₊₂ and GeₘH₂ₘ₊₂, respectively, wherein n and m are whole numbers. The value of x is measured. The method further involves injecting silane gas with a molecular formula SiₙH₂ₙ₊₂ at a flow rate F_{2Si} and a mixture of a carrier gas and germane gas with a dilution d₂ at a flow rate F_{2Gm} into the reaction chamber toward a substrate at a second temperature T₂ (in Kelvin), wherein the silane and germane gases react to deposit a second silicon germanium film with composition Si_{1-y}Ge_{y} onto the substrate. The germane gas has a molecular formula GeₘH₂ₘ₊₂. The value of y is measured. Three parameters are selected from the set comprising (1) a flow rate F_{3Si} of a silane gas with a molecular formula SiₙH₂ₙ₊₂, (2) a flow rate F_{3Gm} of a mixture of a carrier gas and germane gas with a dilution d₃, the germane gas having a molecular formula GeₘH₂ₘ₊₂, (3) a temperature T₃ (in Kelvin), and (4) a concentration z in a silicon germanium composition Si_{1-z}Ge_{z}. Values are assigned to the three selected parameters, and the unselected parameter of said set is calculated from one of the two equations

$$\frac{{F}_{3 Si}}{{F}_{3 Gm}} = {( \frac{1 - z}{z} )}^{2} {( \frac{x}{1 - x} )}^{2} ( \frac{{F}_{1 Si}}{{F}_{1 Gm}} ) ( \frac{{d}_{3}}{{d}_{1}} ) {ⅇ}^{( \frac{E}{R} ) ( \frac{1}{{T}_{1}} - \frac{1}{{T}_{3}} )}$$

$$\frac{{F}_{3 Si}}{{F}_{3 Gm}} = {( \frac{1 - z}{z} )}^{2} {( \frac{y}{1 - y} )}^{2} ( \frac{{F}_{2 Si}}{{F}_{2 Gm}} ) ( \frac{{d}_{3}}{{d}_{2}} ) {ⅇ}^{( \frac{E}{R} ) ( \frac{1}{{T}_{2}} - \frac{1}{{T}_{3}} )}$$

or from one or more equations that are collectively mathematically equivalent to either of the above equations. The term E/R is given by

$$\frac{E}{R} = \frac{ln [ {( \frac{1 - x}{x} )}^{2} {( \frac{y}{1 - y} )}^{2} ( \frac{{F}_{1 Gm}}{{F}_{1 Si}} ) ( \frac{{F}_{2 Si}}{{F}_{2 Gm}} ) ( \frac{{d}_{1}}{{d}_{2}} ) ]}{\frac{1}{{T}_{1}} - \frac{1}{{T}_{2}}} .$$

In another aspect, the invention provides an apparatus for depositing a silicon germanium layer with a targeted composition onto a substrate, comprising a reaction chamber, a source of a silicon-containing precursor gas, a source of a germanium-containing precursor gas, an injector assembly, and a computer unit. The reaction chamber contains a substrate support structure. The injector assembly is connected to the gas sources for injecting the silicon-containing and germanium-containing gases at controllable flow rates into the reaction chamber toward a substrate supported by the substrate support structure. The computer unit is configured to store information associated with a first reaction of the silicon-containing precursor gas injected into the chamber at a flow rate F_{1Si} and the germanium-containing precursor gas injected into the chamber at a flow rate F_{1Ge} by the injector assembly to deposit a first silicon germanium layer with composition Si₁₋ₓGeₓ onto a substrate supported by the substrate support structure. The stored information from the first reaction comprises F_{1Si}, F_{1Ge}, and x. The computer unit is also configured to store information associated with a second reaction of a silicon-containing precursor gas at a flow rate F_{2Si} and a germanium-containing precursor gas at a flow rate F_{2Ge} to deposit a second silicon germanium layer with composition Si_{1-y}Ge_{y}. The stored information from the second reaction comprises only two parameters of the set consisting of F_{2Si}, F_{2Ge}, and y. The computer unit is additionally configured to calculate the unstored parameter of the set consisting of F_{2Si}, F_{2Ge}, and y from the equation

$$\frac{{F}_{2 Si}}{{F}_{2 Ge}} = {( \frac{x}{1 - x} )}^{2} {( \frac{1 - y}{y} )}^{2} ( \frac{{F}_{1 Si}}{{F}_{1 Ge}} ) .$$

In another aspect, the invention provides an apparatus for depositing a silicon germanium layer with a targeted composition onto a substrate, comprising a reaction chamber, sources of SiH₄ gas and GeH₄ gas, an injector assembly, and a computer unit. The reaction chamber contains a substrate support structure. The injector assembly is connected to the SiH₄ and GeH₄ gas sources for injecting SiH₄ gas and GeH₄ gas at controllable flow rates into the reaction chamber toward a substrate supported by the substrate support structure. The computer unit is configured to store information associated with a first reaction of SiH₄ gas injected into the chamber at a flow rate F_{1Si} and GeH₄ gas injected into the chamber at a flow rate F_{1Ge} by the injector assembly to deposit a first silicon germanium layer with composition Si₁₋ₓGeₓ onto a first substrate supported by the substrate support structure. The stored information of the first reaction comprises F_{1Si}, F_{1Ge}, and x. The computer unit is also configured to store information associated with a second reaction of SiH₄ gas at a flow rate F_{2Si} and GeH₄ gas at a flow rate F_{2Ge} to deposit a second silicon germanium layer with composition Si_{1-y}Ge_{y}. The stored information from the second reaction comprises only two parameters of the set consisting of F_{2Si}, F_{2Ge}, and y. The computer unit is additionally configured to calculate the unstored parameter of the set consisting of F_{2Si}, F_{2Ge}, and y from the equation

$$\frac{{F}_{2 Si}}{{F}_{2 Ge}} = {( \frac{x}{1 - x} )}^{2} {( \frac{1 - y}{y} )}^{2} ( \frac{{F}_{1 Si}}{{F}_{1 Ge}} )$$

wherein y is a targeted value of a composition Si_{1-y}Ge_{y} of a silicon germanium layer deposited onto the second substrate by a reaction of the SiH₄ and GeH₄ gases.

In another aspect, the invention provides an apparatus for calculating a parameter associated with a deposition process of a silicon germanium layer, comprising a reaction chamber, a source of silane gas, a source of a mixture of a carrier gas and a germane gas with a dilution d₁, an injector assembly, and a control system. The reaction chamber contains a substrate support structure. The silane gas has a molecular formula SiₙH₂ₙ₊₂, wherein n is a whole number. The germane gas has a molecular formula GeₘH₂ₘ₊₂, wherein m is a whole number. The injector assembly is connected to the gas sources for injecting the silane gas and the mixture of carrier and germane gas at controllable flow rates into the reaction chamber toward a substrate supported by the substrate support structure. The control system is configured to store information associated with a reaction of the silane gas injected into the chamber at a flow rate F_{1Si} and the carrier/germane gas mixture injected into the chamber at a flow rate F_{1Gm} by the injector assembly to deposit a silicon germanium layer with composition Si₁₋ₓGeₓ onto a substrate supported by the substrate support structure. The stored information comprises F_{1Si}, F_{1Gm}, and x. The control system is additionally configured to store assigned values of two selected parameters from the set comprising (1) a flow rate F_{2Si} of a silane gas with a molecular formula SiₙH₂ₙ₊₂, (2) a flow rate F_{2Gm} of a mixture of a carrier gas and a germane gas with a molecular formula GeₘH₂ₘ₊₂ and dilution d₂, and (3) a concentration y in a silicon germanium composition Si_{1-y}Ge_{y}. The control system is configured to calculate the unselected parameter of said set from the equation

$$\frac{{F}_{2 Si}}{{F}_{2 Gm}} = {( \frac{x}{1 - x} )}^{2} {( \frac{1 - y}{y} )}^{2} ( \frac{{d}_{2}}{{d}_{1}} ) ( \frac{{F}_{1 Si}}{{F}_{1 Gm}} )$$

or from one or more equations that are collectively mathematically equivalent to the above equation.

In another aspect, the invention provides an apparatus for depositing a silicon germanium layer with a targeted composition onto a substrate, comprising a reaction chamber, sources of silane gas and germane gas, a gas injector assembly, and a control system. The reaction chamber contains a substrate support structure. The silane gas has a molecular formula SiₙH₂ₙ₊₂, wherein n is a whole number. The germane gas has a molecular formula GeₘH₂ₘ₊₂, wherein m is a whole number. The gas injector assembly is connected to the gas sources for injecting the silane and germane gases at controllable flow rates into the reaction chamber toward a substrate supported by the substrate support structure. The control system is configured to store information associated with a first reaction of the silane gas injected into the chamber at a flow rate F_{1Si} and the germane gas injected into the chamber at a flow rate F_{1Ge} by the gas injector assembly to deposit a first silicon germanium layer with composition Si₁₋ₓGeₓ onto a substrate supported by the substrate support structure at a first substrate temperature T₁ (in Kelvin). The control system is also configured to store information associated with a second reaction of the silane gas injected into the chamber at a flow rate F_{2Si} and the germane gas injected into the chamber at a flow rate F_{2Ge} by the gas injector assembly to deposit a second silicon germanium layer with composition Si_{1-y}Ge_{y} onto a substrate supported by the substrate support structure at a second substrate temperature T₂ (in Kelvin). The stored information of the first and second reactions comprises F_{1Si}, F_{1Ge}, T₁, x, F_{2Si}, F_{2Ge}, T₂, and y. The control system is configured to store information associated with a third reaction of silane gas at a flow rate F_{3Si} and germane gas at flow rate F_{3Ge} to deposit a third silicon germanium layer with composition Si_{1-z}Ge_{z} onto a substrate at a third substrate temperature T₃ (in Kelvin). The stored information of the third reaction comprises only two parameters of the set consisting of F_{3Si}, F_{3Ge}, and z. The control system is additionally configured to calculate the unstored parameter of the set consisting of F_{3Si}, F_{3Ge}, and z from the equations

$$\frac{{F}_{3 Si}}{{F}_{3 Ge}} = {( \frac{1 - z}{z} )}^{2} {( \frac{x}{1 - x} )}^{2} ( \frac{{F}_{1 Si}}{{F}_{1 Ge}} ) {ⅇ}^{( \frac{E}{R} ) ( \frac{1}{{T}_{1}} - \frac{1}{{T}_{3}} )}$$

$$and$$

$$\frac{E}{R} = \frac{ln [ {( \frac{1 - x}{x} )}^{2} {( \frac{y}{1 - y} )}^{2} ( \frac{{F}_{1 Ge}}{{F}_{1 Si}} ) ( \frac{{F}_{2 Si}}{{F}_{2 Ge}} ) ]}{\frac{1}{{T}_{1}} - \frac{1}{{T}_{2}}} .$$

In another aspect, the invention provides an apparatus for calculating a parameter associated with a deposition process of a silicon germanium film, comprising a reaction chamber, a source of silane gas, a source of a mixture of a carrier gas and germane gas with a dilution d, a gas injector assembly, and a control system. The reaction chamber contains a substrate support structure. The silane gas has a molecular formula SiₙH₂ₙ₊₂, wherein n is a whole number. The germane gas has a molecular formula GeₘH₂ₘ₊₂, wherein m is a whole number. The gas injector assembly is connected to the gas sources for injecting the silane gas and the carrier/germane gas mixture at controllable flow rates into the reaction chamber toward a substrate supported by the substrate support structure. The control system is configured to store information associated with a first reaction of the silane gas injected into the chamber at a flow rate F_{1Si} and the carrier/germane gas mixture injected into the chamber at a flow rate F_{1Gm} by the gas injector assembly to deposit a silicon germanium film with composition Si₁₋ₓGeₓ onto a substrate supported by the substrate support structure at a first substrate temperature T₁. The control system is also configured to store information associated with a second reaction of the silane gas injected into the chamber at a flow rate F_{2Si} and the carrier/germane gas mixture injected into the chamber at a flow rate F_{2Gm} by the gas injector assembly to deposit a silicon germanium film with composition Si_{1-y}Ge_{y} onto a substrate supported by the substrate support structure at a second substrate temperature T₂. The stored information comprises F_{1Si}, F_{1Gm}, T₁, x, F_{2Si}, F_{2Gm}, T₂, and y. The control system is additionally configured to store assigned values of three selected parameters from the set comprising (1) a flow rate F_{3Si} of silane gas with a molecular formula SiₙH₂ₙ₊₂, (2) a flow rate F_{3Gm} of a mixture of a carrier gas and germane gas with a dilution d₃, the germane gas having a molecular formula GeₘH₂ₘ₊₂, (3) a temperature T₃ (in Kelvin), and (4) a concentration z in a silicon germanium composition Si_{1-z}Ge_{z}. The control system is configured to calculate the unselected parameter of said set from one of the two equations

$$\frac{{F}_{3 Si}}{{F}_{3 Gm}} = {( \frac{1 - z}{z} )}^{2} {( \frac{x}{1 - x} )}^{2} ( \frac{{F}_{1 Si}}{{F}_{1 Gm}} ) ( \frac{{d}_{3}}{d} ) {ⅇ}^{( \frac{E}{R} ) ( \frac{1}{{T}_{1}} - \frac{1}{{T}_{3}} )}$$

$$\frac{{F}_{3 si}}{{F}_{3 Gm}} = {( \frac{1 - z}{z} )}^{2} {( \frac{y}{1 - y} )}^{2} ( \frac{{F}_{2 Si}}{{F}_{2 Gm}} ) ( \frac{{d}_{3}}{d} ) {ⅇ}^{( \frac{E}{R} ) ( \frac{1}{{T}_{2}} - \frac{1}{{T}_{3}} )}$$

or from one or more equations that are collectively mathematically equivalent to either of the above equations, wherein

$$\frac{E}{R} = \frac{ln [ {( \frac{1 - x}{x} )}^{2} {( \frac{y}{1 - y} )}^{2} ( \frac{{F}_{1 Gm}}{{F}_{1 Si}} ) ( \frac{{F}_{2 Si}}{{F}_{2 Gm}} ) ]}{\frac{1}{{T}_{1}} - \frac{1}{{T}_{2}}} .$$

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIG. 1 is a schematic sectional view of an exemplary single-substrate reaction chamber for use with preferred embodiments of the invention.

FIG. 2 is a gas flow schematic, illustrating exemplary reactant and carrier gas sources in accordance with preferred embodiments of the invention.

FIG. 2A is a gas flow schematic illustrating the use of a controller, in accordance with preferred embodiments of the invention.

FIG. 3 is an experimentally produced plot of x/(1−x) versus the gas phase ratio for a reaction of monosilane with monogermane at steady state pressure and temperature to produce a Si₁₋ₓGeₓ film, for several different process temperatures.

FIG. 4 is an experimentally produced plot of [x/(1−x)]² versus the gas phase ratio for a reaction of monosilane with monogermane at steady state pressure and temperature to produce a Si₁₋ₓGeₓ film, for several different process temperatures.

FIG. 5 is an experimentally produced Arrhenius plot of the natural log of m versus 1/T for the deposition of epitaxial SiGe layers, where T is the reaction temperature in Kelvin.

### DETAILED DESCRIPTION OF THE PREFERRED EMBODIMENTS

Preferred Reactor

Preferred embodiments of the present invention involve the growth of SiGe films on substrates within semiconductor reactors. It is thus helpful to first describe a preferred reactor and accompanying apparatus.

While the preferred embodiments are presented in the context of a single-substrate, horizontal flow cold-wall reactor, it will be understood that certain aspects of the invention will have application to various types of reactors known in the art and that the invention is not limited to the disclosed type of reactor. For example, batch reactors can be used and advantageously allow for increased throughput due to the ability to simultaneously process a plurality of semiconductor wafers. A suitable batch reactor is available commercially under the trade name A412™ from ASM International, N.V. of The Netherlands.

Nevertheless, use of a single-substrate, horizontal flow cold-wall reactor is particularly advantageous. For example, the illustrated single-pass horizontal flow design enables laminar flow of reactant gases, with low residence times. This in turn facilitates rapid sequential processing, particularly in the cyclical deposition methods that are typical of semiconductor processing, while minimizing reactant interaction with each other and with chamber surfaces. Such a laminar flow enables sequentially flowing reactants that might react with each other. Reactions to be avoided include highly exothermic or explosive reactions, such as produced by oxygen and hydrogen-bearing reactants, and reactions that produce particulate contamination of the chamber. The skilled artisan will recognize, however, that for certain sequential processes, other reactor designs can also be provided for achieving these ends, provided sufficient purge or evacuation times are allowed to remove incompatible reactants.

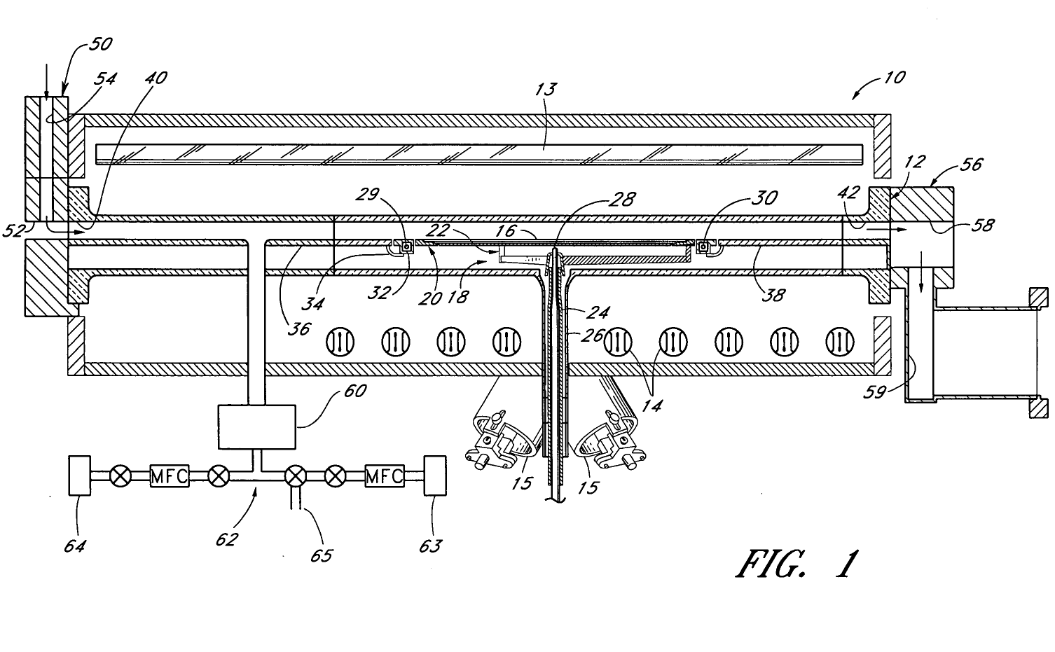

FIG. 1 shows a chemical vapor deposition (CVD) reactor 10, including a quartz process or reaction chamber 12, constructed in accordance with a preferred embodiment, and for which the methods disclosed herein have particular utility. The superior processing control of the reactor 10 has utility in CVD of a number of different materials and can safely and cleanly accomplish multiple treatment steps sequentially in the same chamber 12. The basic configuration of the reactor 10 is available commercially under the trade name Epsilon® from ASM America, Inc. of Phoenix, Ariz.

A plurality of radiant heat sources are supported outside the chamber 12 to provide heat energy in the chamber 12 without appreciable absorption by the quartz chamber 12 walls. The illustrated radiant heat sources comprise an upper heating assembly of elongated tube-type radiant heating elements 13. The upper heating elements 13 are preferably disposed in spaced-apart parallel relationship and also substantially parallel with the reactant gas flow path through the underlying reaction chamber 12. A lower heating assembly comprises similar elongated tube-type radiant heating elements 14 below the reaction chamber 12, preferably oriented transverse to the upper heating elements 13. Desirably, a portion of the radiant heat is diffusely reflected into the chamber 12 by rough specular reflector plates above and below the upper and lower lamps 13, 14, respectively. Additionally, a plurality of spot lamps 15 supply concentrated heat to the underside of the substrate support structure (described below), to counteract a heat sink effect created by cold support structures extending through the bottom of the reaction chamber 12.

Each of the elongated tube-type heating elements 13, 14 is preferably a high intensity tungsten filament lamp having a transparent quartz envelope containing a halogen gas, such as iodine. Such lamps produce full-spectrum radiant heat energy transmitted through the walls of the reaction chamber 12 without appreciable absorption. As is known in the art of semiconductor processing equipment, the power of the various lamps 13, 14, 15 can be controlled independently or in grouped zones in response to temperature sensors. The skilled artisan will appreciate, however, that the principles and advantages of the processes described herein can be achieved with other heating and temperature control systems.

A substrate 16, preferably comprising a silicon wafer, is shown supported within the reaction chamber 12 upon a substrate support structure 18. While the substrate 16 of the illustrated embodiment is a single-crystal silicon wafer, it will be understood that the term “substrate” broadly refers to any generally planar element on which a layer is to be deposited. Moreover, thin, uniform layers are often required on other substrates, including, without limitation, the deposition of optical thin films on glass or other substrates.

The illustrated support structure 18 includes a substrate holder 20 upon which the substrate 16 rests, and which is in turn supported by a support spider 22. The spider 22 is mounted to a shaft 24, which extends downwardly through a tube 26 depending from the chamber lower wall. Preferably, the tube 26 communicates with a source of purge or sweep gas which can flow during processing, inhibiting process gases from escaping to the lower section of the chamber 12. Preferably, the shaft 24 is configured to be rotated about a central vertical axis so that the spider 22, holder 20, and substrate 16 can be rotated during processing, which advantageously improves processing uniformity across the substrate surface. A suitable motor can be provided for rotating these elements.

A plurality of temperature sensors are positioned in proximity to the substrate 16. The temperature sensors can take any of a variety of forms, such as optical pyrometers or thermocouples. The number and positions of the temperature sensors are selected to promote temperature uniformity. In the illustrated reaction 10, the temperature sensors directly or indirectly sense the temperature of positions in proximity to the substrate 16.

In the illustrated embodiment, the temperature sensors comprise thermocouples, including a first or central thermocouple 28, suspended below the substrate holder 20 in any suitable fashion. The illustrated central thermocouple 28 passes through the spider 22 in proximity to the substrate holder 20. The reactor 10 further includes a plurality of secondary or peripheral thermocouples, also in proximity to the substrate 16, including a leading edge or front thermocouple 29, a trailing edge or rear thermocouple 30, and a side thermocouple (not shown). Each of the peripheral thermocouples is housed within a slip ring 32, which surrounds the substrate holder 20 and the substrate 16. Each of the central and peripheral thermocouples is connected to a temperature controller, which sets the power of the various heating elements 13, 14, 15 in response to the readings of the thermocouples.

In addition to housing the peripheral thermocouples, the slip ring 32 absorbs and emits radiant heat during high temperature processing, such that it compensates for a tendency toward greater heat loss or absorption at substrate edges, a phenomenon which is known to occur due to a greater ratio of surface area to volume in regions near such edges. By minimizing edge losses, the slip ring 32 can reduce the risk of radial temperature non-uniformities across the substrate 16. The slip ring 32 can be suspended by any suitable means. For example, the illustrated slip ring 32 rests upon elbows 34 which depend from a front chamber divider 36 and a rear chamber divider 38. The dividers 36, 38 desirably are formed of quartz. In some arrangements, the rear divider 38 can be omitted.

The illustrated reaction chamber 12 includes an inlet port 40 for the injection of reactant and carrier gases, and the substrate 16 can also be received therethrough. An outlet port 42 is on the opposite side of the chamber 12, with the substrate support structure 18 positioned between the inlet 40 and outlet 42.

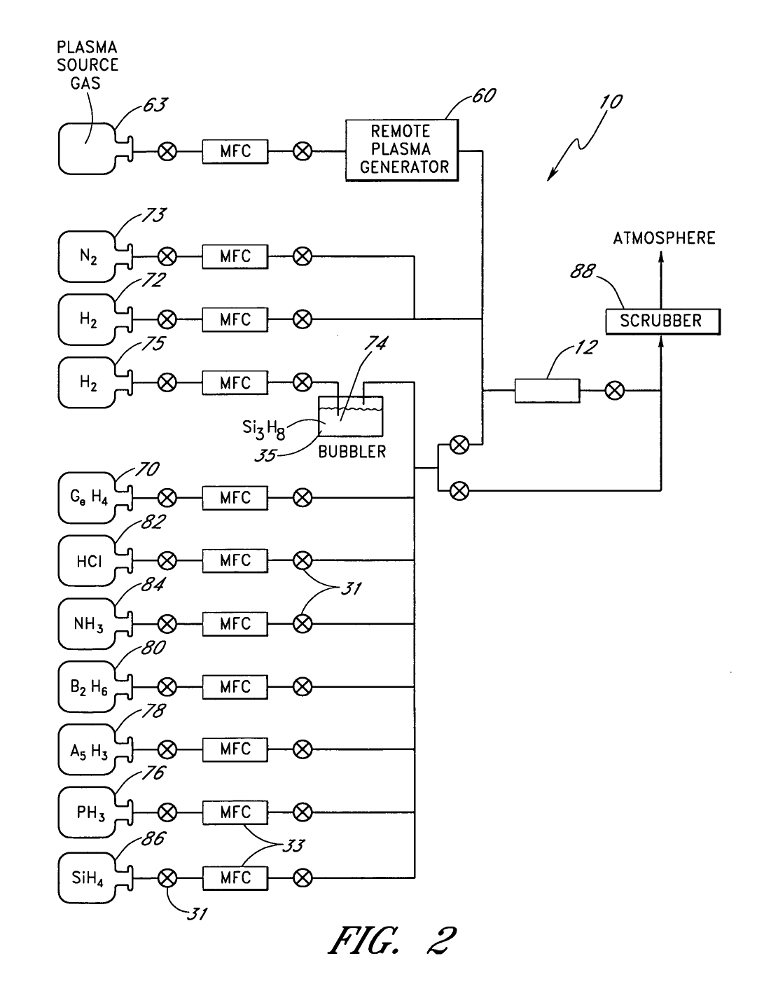

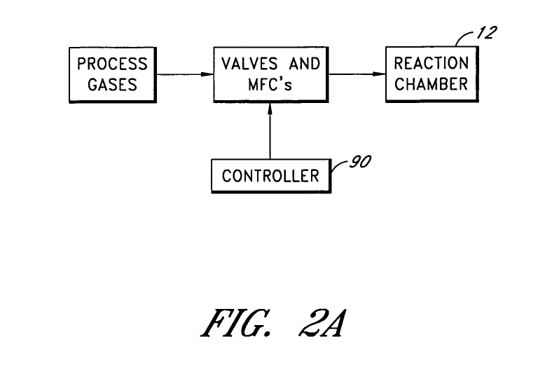

An inlet component 50 is fitted to the reaction chamber 12, adapted to surround the inlet port 40, and includes a horizontally elongated slot 52 (i.e., elongated in a direction perpendicular to the plane of FIG. 1) through which the substrate 16 can be inserted. A generally vertical inlet 54 receives gases from remote sources, as will be described more fully with respect to FIG. 2, and communicates such gases with the slot 52 and the inlet port 40. The inlet 54 can include gas injectors as described in U.S. Pat. No. 5,221,556, issued to Hawkins et al., or as described with respect to FIGS. 21-26 in U.S. Pat. No. 6,093,252, issued to Wengert et al. Such injectors are designed to maximize uniformity of gas flow for the single-substrate reactor.

An outlet component 56 similarly mounts to the process chamber 12 such that an exhaust opening 58 aligns with the outlet port 42 and leads to exhaust conduits 59. The conduits 59, in turn, can communicate with suitable vacuum means (not shown) for drawing process gases through the chamber 12. In the preferred embodiment, process gases are drawn through the reaction chamber 12 and a downstream scrubber 88 (FIG. 2). A pump or fan is preferably included to help draw process gases through the chamber 12, and to evacuate the chamber for low pressure processing.

The reactor 10 can also include a source 60 of excited species, preferably positioned upstream from the chamber 10. The excited species source 60 of the illustrated embodiment comprises a remote plasma generator, including a magnetron power generator and an applicator along a gas line 62. An exemplary remote plasma generator is available commercially under the trade name TRW-850 from Rapid Reactive Radicals Technology (R3T) GmbH of Munich, Germany. In the illustrated embodiment, microwave energy from a magnetron is coupled to a flowing gas in an applicator along a gas line 62. A source of precursor gases 63 is coupled to the gas line 62 for introduction into the excited species generator 60. The illustrated embodiment employs nitrogen as a precursor gas. A separate source of carrier gas 64 can also be coupled to the gas line 62, though in embodiments employing N₂ as a precursor, separate carrier gas can be omitted. One or more further branch lines 65 can also be provided for additional reactants. Each gas line can be provided with a separate mass flow controller (MFC) and valves, as shown, to allow selection of relative amounts of carrier and reactant species introduced to the generator 60 and thence into the reaction chamber 12. Preferred embodiments of the present invention do not utilize the excited species source 60, which is described herein primarily to provide a complete description of the preferred reactor 10.

Substrates are preferably passed from a handling chamber (not shown), which is isolated from the surrounding environment, through the slot 52 by a pick-up device. The handling chamber and the process chamber 12 are preferably separated by a gate valve (not shown), such as a slit valve with a vertical actuator, or a valve of the type disclosed in U.S. Pat. No. 4,828,224.

The total volume capacity of a single-substrate process chamber 12 designed for processing 200 mm wafers, for example, is preferably less than about 30 liters, more preferably less than about 20 liters, and most preferably less than about 10. The illustrated chamber 12 has a capacity of about 7.5 liters. Because the illustrated chamber 12 is divided by the dividers 32, 38, substrate holder 20, ring 32, and the purge gas flowing from the tube 26, however, the effective volume through which process gases flow is around half the total volume (about 3.77 liters in the illustrated embodiment). Of course, it will be understood that the volume of the single-wafer process chamber 12 can be different, depending upon the size of the substrates for which the chamber 12 is designed to accommodate. For example, a single-wafer process chamber 12 of the illustrated type, but for 300 mm wafers, preferably has a capacity of less than about 100 liters, more preferably less than about 60 liters, and most preferably less than about 30 liters. One 300 mm wafer process chamber has a total volume of about 24 liters, with an effective processing gas capacity of about 11.83 liters. The relatively small volumes of such chambers desirably allow rapid evacuation or purging of the chamber between phases of the cyclical process described below.

FIG. 2 schematically shows a gas flow control and injector assembly in accordance with the preferred embodiment. The reactor 10 is typically provided with a variety of different sources of precursors, dopants, carrier gases, etchants, and other materials used in substrate processing. It will be understood that the reactor 10 may include additional or different source materials than shown in FIG. 2. The reactor 10 also includes a number of gas lines through which the gases are communicated to the inlet 54 (FIG. 1) of the reaction chamber 12. The gas lines include attendant safety and control valves 31 (depicted as X's circumscribed by circles) and mass flow controllers 33 (MFC's). The valves 31 provide control over which materials are permitted to flow into the reaction chamber 12, and the mass flow controllers 33 control the flow rates of said materials. Preferably, each mass flow controller 33 is configured to provide a relatively steady flow of process gas into the chamber 12. The mass flow controllers 33 are preferably coordinated at a gas panel. After passing through the process chamber 12, unreacted process gases and gaseous reaction byproducts are exhausted to a scrubber 88 to condense environmentally dangerous fumes before exhausting to the atmosphere.

Preferably, a control system is provided for automatically or electronically operating the valves 31 and mass flow controllers 33 to control substrate processing in accordance with programmed instructions and/or received process parameters. FIG. 2A is a schematic representation of the gas flow system including a controller 90. In the illustrated embodiment, the controller 90 controls the valves 31 and mass flow controllers 33 electronically in accordance with programmed instructions and received process parameters. The controller 90 preferably comprises a computer system or unit. Thus, process gases are communicated to the inlet 54 (FIG. 1) in accordance with directions programmed into the central controller 90 and distributed into the process chamber 12 through one or more gas injectors. The methods and/or equations of the present invention can be incorporated into software, hardware, or a combination of software and hardware for (1) assisting process engineers in the selection of parameters for silicon germanium deposition, and/or (2) directly controlling the process parameters based on received inputs. Desirably, the control system includes a storage for storing process parameters and received or measured reaction data. Preferably, the control system is configured to calculate process parameters for desired silicon germanium films, as described more fully below. More preferably, the control system is configured to perform at least one action from the set comprising (1) storing calculated parameters in the storage, (2) displaying calculated parameters for the benefit of process engineers, and (3) using calculated parameters as process parameters in the deposition of silicon germanium layers onto substrates.

As used herein, an “injector assembly” is an assembly of components configured to inject one or more process gases into a reaction chamber. An injector assembly may include gas flow lines, MFC's, valves, gas-injection orifices (such as the one described with respect to FIGS. 21-26 of U.S. Pat. No. 6,093,252), and the like.

As shown in FIG. 2, the reactor 10 includes a source 72 of hydrogen gas (H₂). As is known in the art, hydrogen is a useful carrier gas for the reactant gases because it can be provided in very high purity, due to its low boiling point, and is compatible with silicon deposition. Hydrogen is also a useful purge gas. The reactor 10 can also include a source 73 of nitrogen gas (N₂). As is known in the art, N₂ is often employed in place of H₂ as a carrier or purge gas in semiconductor fabrication. Nitrogen gas is relatively inert and compatible with many integrated materials and process flows. Other possible carrier gases include noble gases, such as helium (He) or argon (Ar).

As shown in FIG. 2, the reactor 10 includes a source 86 of silane precursor, which is depicted as monosilane gas, SiH₄. As explained below, the invention encompasses the use of silane gas with molecular formula SiₙH₂ₙ₊₂ as a precursor in the formation of SiGe films. Thus, for example, the reactor 10 may include a source of disilane gas Si₂H₆ or trisilane Si₃H₈. In the latter case, the trisilane is typically provided as a liquid 74 in a bubbler 35. A carrier gas source 75, preferably comprising H₂ gas, for bubbling liquid phase trisilane 74 and carrying vapor phase reactants from the bubbler 35 to the reaction chamber 12 is also shown. The bubbler holds liquid trisilane 74 as a silicon source, while a gas line serves to bubble the carrier gas through the liquid silicon source and transport the precursors to the reaction chamber 12 in gaseous form. It will be understood that additional or alternative SiₙH₂ₙ₊₂ sources can be provided.

The illustrated reactor 10 also includes a source 70 of germane gas precursor, which is depicted as monogermane GeH₄. As explained below, the invention encompasses the use of germane gas with molecular formula GeₘH₂ₘ₊₂ as a precursor in the formation of SiGe films. Thus, for example, the reactor 10 may include a source of digermane gas Ge₂H₆ or trigermane gas Ge₃H₈. It will be understood that additional or alternative GeₘH₂ₘ₊₂ sources can be provided.

In addition, another source 63 of nitrogen, such as diatomic nitrogen (N₂), can be provided to the remote plasma generator 60 to provide active species for reaction with deposited silicon layers in the chamber 12. An ammonia (NH₃) source 84 can additionally or alternatively be provided to serve as a volatile nitrogen source for thermal nitridation. Moreover, as is known in the art, any other suitable nitrogen source can be employed and flowed directly, or through remote plasma generator 60, into the chamber 12. In other arrangements, the gas source 63 can comprise a source of other reactant radicals for forming silicon-containing compound layers (e.g., O, C, Ge, metal, etc.).

The reactor 10 can also be provided with a source of oxidizing agent or oxidant. The oxidant source can comprise any of a number of known oxidants, particularly a volatile oxidant such as O₂, NO, H₂O, N₂O, HCOOH, HClO₃. Desirably, the reactor 10 will also include other source gases such as dopant sources (e.g., the illustrated phosphine 76, arsine 78 and diborane 80 sources) and etchants for cleaning the reactor walls and other internal components (e.g., HCl source 82 or NF₃/Cl₂ (not shown) provided through the excited species generator 60). The HCl source 82 can also be used in combination with silicon-containing sources in a tuned₁ selective etching process in which the HCl etches silicon that deposits on oxide layers while silicon grows more rapidly on underlying silicon surfaces.

As discussed above, in addition to conventional gas sources, the preferred reactor 10 includes the excited species source 60 positioned remotely or upstream of the reaction chamber 12. The illustrated source 60 couples microwave energy to gas flowing in an applicator, where the gas includes reactant precursors from the reactant source 63. A plasma is ignited within the applicator, and excited species are carried toward the chamber 12. Preferably, of the excited species generated by the source 60, overly reactive ionic species substantially recombine prior to entry into the chamber 12. On the other hand, N radicals can survive to enter the chamber 12 and react as appropriate.

Additionally, the plasma can be generated in situ, in the reaction chamber. Such an in situ plasma, however, may cause damage, uniformity and roughness problems with some deposited layers. Consequently, where a plasma is used, a remotely generated plasma is typically preferred.

SiGe Control at Constant Temperature

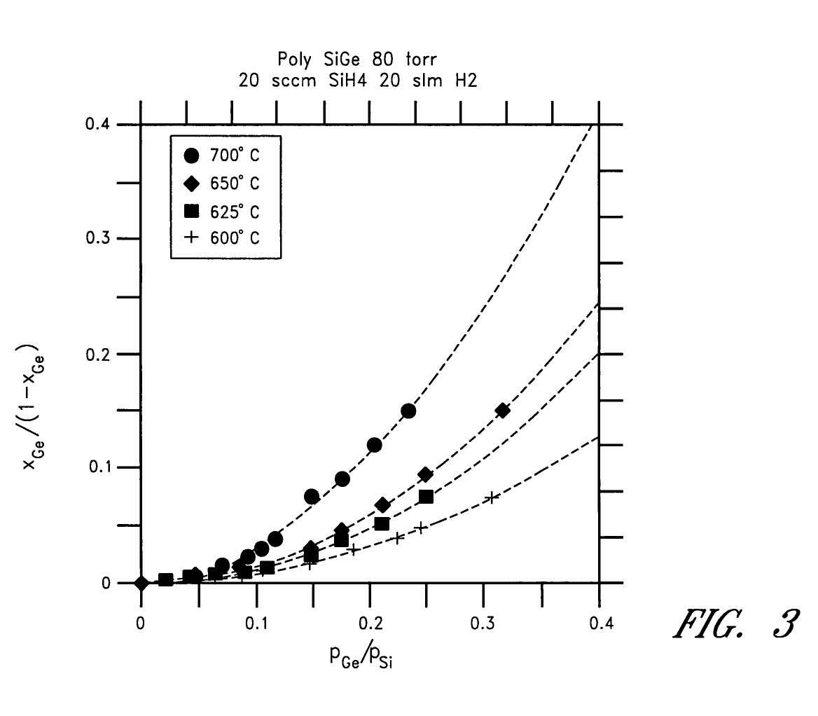

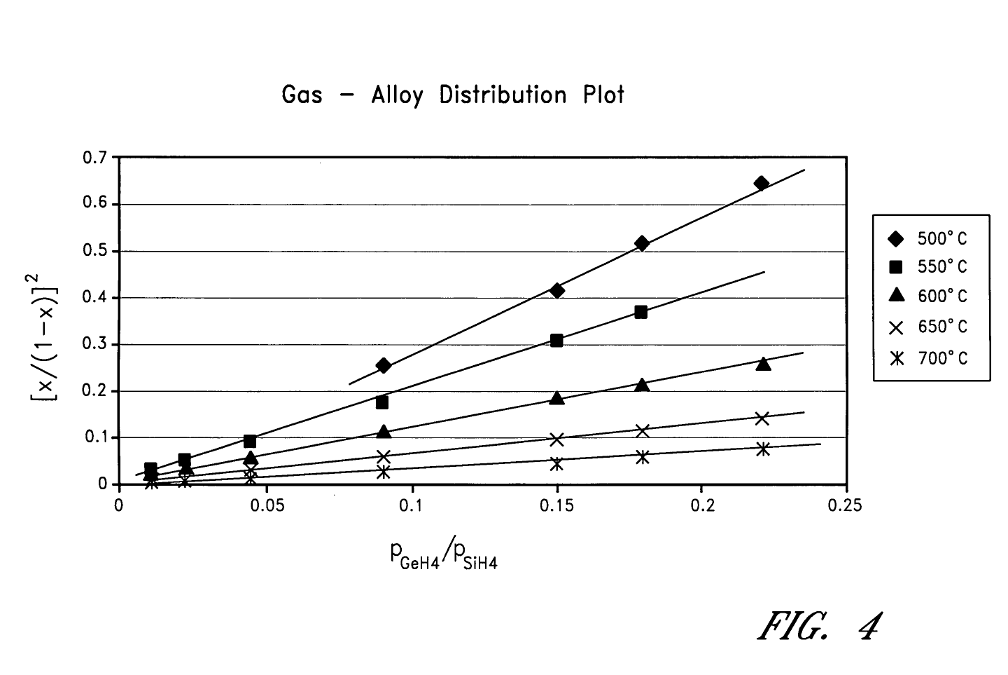

The inventors of the present invention have discovered that, despite prior claims extrapolated from experimental data obtained from UHVCVD reactors, Equation 1 (see Background Section) does not reliably estimate the CVD growth of Si₁₋ₓGeₓ from precursors SiH₄ and GeH₄ under certain conditions. FIGS. 3 and 4 are plots of the ratios x/(1−x) and [x/(1−x)]², respectively, versus the gas phase ratio P_{GeH4}/P_{SiH4} associated with a number of experimental reactions of SiH₄ with GeH₄ in the presence of H₂ carrier gas, to produce polycrystalline layers of Si₁₋ₓGeₓ. The reactions were conducted at a steady state pressure of 80 torr and steady state temperatures of 600° C., 625° C., 650° C., and 700° C. The germanium concentration x of each deposited film was subsequently measured. In each case, the flow rate of SiH₄ was 20 sccm, with the GeH₄ flow rates varying by reaction.

As shown in FIG. 3, the relationship between x/(1−x) and the gas phase ratio P_{GeH4}/P_{SiH4} was found to be non-linear. This finding is inconsistent with the conventionally understood relationship expressed as Equation 1, in which m is considered to be a constant at steady state temperature and pressure. In contrast, as shown in FIG. 4, the relationship between [x/(1−x)]² and the gas phase ratio P_{GeH4}/P_{SiH4} was found to be linear. As noted above, the experimental data from which Equation 1 was extrapolated (in the prior art) was obtained from UHVCVD reactors, which operate at extremely low pressures (e.g., 10⁻⁵ torr). However, many CVD reactions take place at higher pressures, often within 10-80 torr, which may account for the erroneousness of Equation 1.

Thus, for this higher pressure range, the CVD growth of Si₁₋ₓGeₓ from precursors SiH₄ and GeH₄ is more accurately modeled as

$${( \frac{x}{1 - x} )}^{2} = m ( \frac{{P}_{{GeH}_{4}}}{{P}_{{SiH}_{4}}} ) . \qquad ( 5 )$$

Moreover, the inventors have determined that this relationship applies, within the kinetic regime, more generally for a reaction of a silane precursor with molecular formula SiₙH₂ₙ₊₂ and a germane precursor with molecular formula GeₘH₂ₘ₊₂, where n and m are whole numbers. As used herein, the term “silane” refers to a substance with molecular formula SiₙH₂ₙ₊₂ (e.g., monosilane SiH₄, disilane Si₂H₆, trisilane Si₃H₈, etc.), and the term “germane” refers to a substance with molecular formula GeₘH₂ₘ₊₂ (e.g., monogermane GeH₄, digermane Ge₂H₆, trigermane Ge₃H₈, etc.). Thus, the CVD growth of Si₁₋ₓGeₓ from precursors silane and germane is more accurately modeled as

$${( \frac{x}{1 - x} )}^{2} = m ( \frac{{P}_{Ge}}{{P}_{Si}} ) \qquad ( 6 )$$

where P_{Si} and P_{Ge} are the partial pressures of the silane and germane precursors, respectively. From Equation 6, the parameters x, P_{Ge}, and P_{Si} can be solved as follows:

$$\begin{matrix}x = \frac{\frac{{mP}_{Ge}}{{P}_{Si}} - {( \frac{{mP}_{Ge}}{{P}_{Si}} )}^{0.5}}{\frac{{mP}_{Ge}}{{P}_{Si}} - 1} & ( 7 ) \\ {P}_{Si} = {{mP}_{Ge} ( \frac{1 - x}{x} )}^{2} & ( 8 ) \\ {P}_{Ge} = {( \frac{x}{1 - x} )}^{2} ( \frac{{P}_{Si}}{m} ) & ( 9 )\end{matrix}$$

Suppose that the reaction takes place in a reaction chamber (such as that shown in FIG. 1) in which the silane gas is injected at a flow rate F_{Si} and the germane gas is injected at a flow rate F_{Ge}. Also, let P and F be the total pressure and flow rate, respectively, after taking into consideration the flow of carrier gas (e.g., H₂). It is understood that the ratio of each precursor's partial pressure to the total pressure is equal to the ratio of the precursor's flow rate to the total flow rate:

$$\begin{matrix}\frac{{P}_{Si}}{P} = \frac{{F}_{Si}}{F} & ( 10 ) \\ \frac{{P}_{Ge}}{P} = \frac{{F}_{Ge}}{F} & ( 11 )\end{matrix}$$

Solving for the ratio of partial pressures yields the relationship:

$$\frac{{P}_{Ge}}{{P}_{Si}} = \frac{{F}_{Ge}}{{F}_{Si}} \qquad ( 12 )$$

Equations 6-9 can be rewritten by substituting the ratio of the precursor flow rates for the gas phase ratio (Equation 12), yielding the equations:

$$\begin{matrix}{( \frac{x}{1 - x} )}^{2} = m ( \frac{{F}_{Ge}}{{F}_{Si}} ) & ( 13 ) \\ x = \frac{\frac{m {F}_{Ge}}{{F}_{Si}} - {( \frac{m {F}_{Ge}}{{F}_{Si}} )}^{0.5}}{\frac{m {F}_{Ge}}{{F}_{Si}} - 1} & ( 14 ) \\ {F}_{Si} = m {{F}_{Ge} ( \frac{1 - x}{x} )}^{2} & ( 15 ) \\ {F}_{Ge} = {( \frac{x}{1 - x} )}^{2} ( \frac{{F}_{Si}}{m} ) & ( 16 )\end{matrix}$$

Suppose a Si₁₋ₓGeₓ film is grown at a given reaction temperature and pressure by injecting silane and germane gases into a reaction chamber at flow rates F_{Si} and F_{Ge}, respectively. Suppose further that the germanium concentration x is subsequently measured. Equation 13 can be used to compute the value of m at that particular temperature and pressure. Once the value of m is known at the given reaction temperature and pressure, Equation 14 can be used to determine the extent to which changes of the precursor flow rates affect the germanium concentration for subsequent reactions at the same temperature and pressure. Equation 15 can be used to determine the appropriate silane flow rate in the case where the process engineer wishes to target a certain germanium concentration and constrain the germane flow rate to a certain value. Equation 16 can be used determine the appropriate germane flow rate in the case where the process engineer wishes to target a certain germanium concentration and constrain the silane flow rate to a certain value.

To illustrate this computation more fully, suppose a first reaction of silane at flow rate F_{1Si} and germane at flow rate F_{1Ge} takes place in a reaction chamber at a steady state temperature T₁ and pressure P₁. The pressure P₁ is controlled primarily by the flow of a carrier gas (e.g., H₂), which is typically much greater than the flow rates of the precursors. The first reaction results in the growth of a silicon germanium film Si₁₋ₓGeₓ. From Equation 13, the value of m{T₁, P₁} at the reaction temperature T₁ and pressure P₁ is solved as

$$m ( {T}_{1} , {P}_{1} ) = {( \frac{x}{1 - x} )}^{2} ( \frac{{F}_{1 Si}}{{F}_{1 Ge}} ) \qquad ( 17 )$$

Now suppose a process engineer wishes to conduct a second reaction at the same temperature T₁ and pressure P₁, with silane injected into the reaction chamber at a flow rate F_{2Si} and germane injected at a flow rate F_{2Ge}. The second reaction will result in the growth of a silicon germanium film Si_{1-y}Ge_{y}. From Equation 13, the ratio of the flow rates of the second reaction is given as follows:

$$\frac{{F}_{2 Si}}{{F}_{2 Ge}} = m ( {T}_{1} , {P}_{1} ) {( \frac{1 - y}{y} )}^{2} \qquad ( 18 )$$

Substituting Equation 17 into Equation 18 yields

$$\frac{{F}_{2 Si}}{{F}_{2 Ge}} = {( \frac{x}{1 - x} )}^{2} {( \frac{1 - y}{y} )}^{2} ( \frac{{F}_{1 Si}}{{F}_{1 Ge}} ) \qquad ( 19 )$$

Prior to conducting the second reaction, the process engineer can select values for two of the three parameters F_{2Si}, F_{2Ge}, and y. Then, Equation 19 can be used to calculate the value of the unselected parameter. For example, if a specific value for the germanium concentration y is to be targeted, and if a specific value for the silane flow rate F_{2Si} is selected, then Equation 19 can be used to calculate the required flow rate F_{2Ge} of the germane precursor. In another example, if specific flow rates F_{2Si} and F_{2Ge} for the precursors are selected, then Equation 19 can be used to determine what will be the germanium concentration y in the silicon germanium film. Alternatively, the value of m can be calculated from Equation 17, and then the germanium concentration y can be calculated from Equation 14 by substituting the values of F_{2Si} and F_{2Ge}. This method has been observed to work in the kinetic regime, even at its boundary with the mass transport limited regime.

Germane gas is typically sold in an impure state, mixed with a carrier gas such as hydrogen. Thus, a source of germane gas is normally given a dilution rating, which is the mass ratio of the germane gas to the total mixture of germane and the carrier. For example, if a source of germane gas has a dilution of 1.5%, the source comprises 98.5% carrier gas. If the flow rate of the germane/carrier mixture is F_{Gm} and the dilution is d, then
F_{Ge}=dF_{Gm} (20)

Based on this relationship, Equations 13-19 can be rewritten as follows:

$$\begin{matrix}{( \frac{x}{1 - x} )}^{2} = \frac{{mdF}_{Gm}}{{F}_{Si}} & ( 21 ) \\ x = \frac{\frac{{mdF}_{Gm}}{{F}_{Si}} - {( \frac{{mdF}_{Gm}}{{F}_{Si}} )}^{0.5}}{\frac{{mdF}_{Gm}}{{F}_{Si}} - 1} & ( 22 ) \\ {F}_{Si} = {{mdF}_{Gm} ( \frac{1 - x}{x} )}^{2} & ( 23 ) \\ {F}_{Gm} = {( \frac{x}{1 - x} )}^{2} ( \frac{{F}_{Si}}{md} ) & ( 24 ) \\ m ( {T}_{1} , {P}_{1} ) = {( \frac{x}{1 - x} )}^{2} ( \frac{{F}_{1 Si}}{{d}_{1} {F}_{1 Gm}} ) & ( 25 ) \\ \frac{{F}_{2 Si}}{{F}_{2 Gm}} = {d}_{2} m ( {T}_{1} , {P}_{1} ) {( \frac{1 - y}{y} )}^{2} & ( 26 ) \\ \frac{{F}_{2 Si}}{{F}_{2 Gm}} = {( \frac{x}{1 - x} )}^{2} {( \frac{1 - y}{y} )}^{2} ( \frac{{d}_{2}}{{d}_{1}} ) ( \frac{{F}_{1 Si}}{{F}_{1 Gm}} ) & ( 27 )\end{matrix}$$

In these equations, the terms d₁ and d₂ are the dilution ratings of germane sources used in the first and second reactions, respectively. In many cases, the same germane source will be used in successive reactions, in which case d₁ equals d₂ and the ratio d₂/d₁ equals 1.
SiGe Control with Temperature Variation

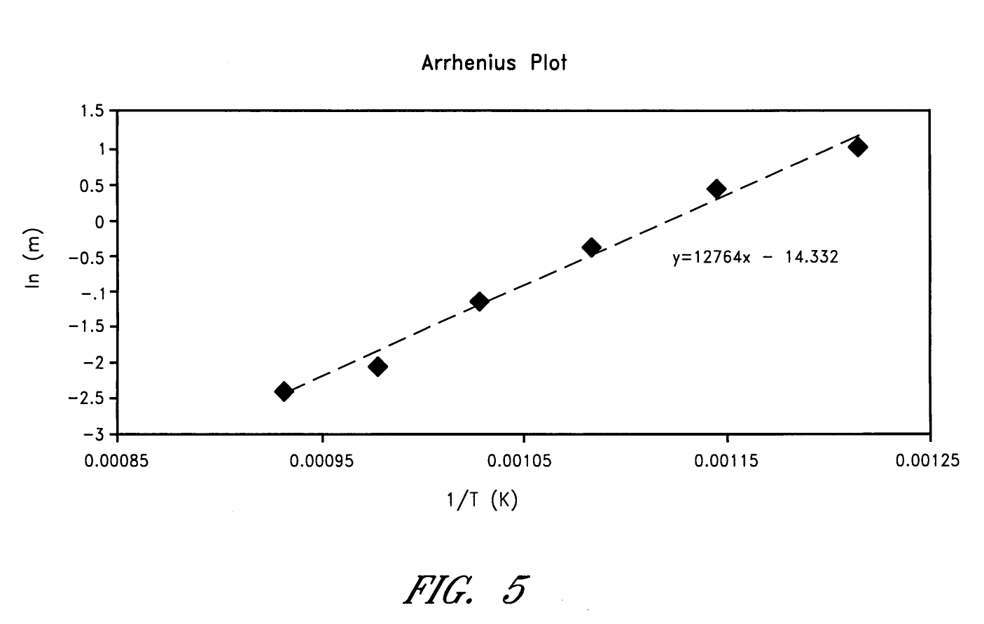

FIG. 5 is an Arrhenius plot of the natural log of m (calculated from Equation 13 or 21) versus 1/T, where T is the reaction temperature in degrees Kelvin, for a plurality of experimental reactions of SiH₄ and GeH₄ to produce epitaxial layers of SiGe on semiconductor substrates. The reactions were conducted at various temperatures and at a constant pressure of 80 torr. Each of the reactions involved the same flow rates of the SiH₄ and GeH₄ precursors. FIG. 5 demonstrates a linear relationship between 1n(m) and 1/T. A best-fit line for the illustrated data points can be represented as follows:

$$ln ( m ) = ( 12764 K . ) ( \frac{1}{T} ) - 14.332 \qquad ( 28 )$$

If it is assumed that the relationship between m and T emulates an Arrhenius function, then

$$\begin{matrix}m ( T ) = A {ⅇ}^{\frac{- E}{RT}} & ( 29 ) \\ ln ( m ) = ln ( A ) - ( \frac{E}{R} ) ( \frac{1}{T} ) & ( 30 )\end{matrix}$$

where A is a constant, E is the activation energy per mole associated with the reaction of the precursors, and R is the universal gas constant 8.314×10⁻³ kJmol⁻¹K⁻¹. If Equations 29 and 30 are true, then Equation 28 dictates that −E/R equals 12764 K, and 1n(A) equals −14.332. From this information, E is solved as −106.1 kJ/mol and A is solved as 5.97×10⁻⁷. It is known that the reaction of monosilane with monogermane to produce silicon germanium involves an activation energy of 96 kJ/mol (absolute value). The fact that the calculated activation energy is roughly equal to the known activation energy for the reaction validates to some extent the correctness of Equations 29 and 30. The difference between the calculated and known values of E arises due to imprecision of the experimental data. As a practical matter, it can be difficult to control the flow rates of the precursors and the carrier gas with an extremely high degree of accuracy. It is expected that as the number of experiments increases, the average of the calculated values of E will approach the known activation energy associated with the reaction.

Suppose two reactions of silane and germane gases are conducted at first and second temperatures T₁ and T₂, respectively, to deposit silicon germanium films onto first and second substrates. The term m for each reaction can be expressed as follows:

$$\begin{matrix}{m}_{1} = m ( {T}_{1} ) = A {ⅇ}^{\frac{- E}{{RT}_{1}}} & ( 31 ) \\ {m}_{2} = m ( {T}_{2} ) = A {ⅇ}^{\frac{- E}{{RT}_{2}}} & ( 32 )\end{matrix}$$

Then, the ratio E/R and the constant A can be solved as follows:

$$\begin{matrix}\frac{E}{R} = \frac{ln ( {m}_{2} ) - ln ( {m}_{1} )}{\frac{1}{{T}_{1}} - \frac{1}{{T}_{2}}} & ( 33 ) \\ A = {m}_{1} {ⅇ}^{\frac{E}{{RT}_{1}}} & ( 34 ) \\ A = {m}_{2} {ⅇ}^{\frac{E}{{RT}_{2}}} & ( 35 )\end{matrix}$$

It will be appreciated that Equations 34 and 35 will yield the same value of A. Once the constant A is determined, the value of m can be calculated for any temperature from Equation 29.

Suppose a first reaction of silane gas at a flow rate F_{1Si} and a gaseous mixture of germane and a carrier with dilution d₁ at a flow rate F_{1Gm} takes place at a temperature T₁ and pressure P to deposit a silicon germanium film Si₁₋ₓGeₓ onto a first substrate, with the germanium concentration x being subsequently measured. Suppose further that a second reaction of silane gas at flow rate F_{2Si} and a gaseous mixture of germane and a carrier with dilution d₂ at flow rate F_{2Gm} takes place at a temperature T₂ and pressure P to deposit a silicon germanium film Si_{1-y}Ge_{y} onto a second substrate, with the germanium concentration y being subsequently measured. Now suppose that a third reaction is contemplated at a temperature T₃ and pressure P, wherein a silane gas and germane gas mixture with dilution d₃ will be injected at flow rates F_{3Si} and F_{3Gm}, respectively. The third reaction will result in the deposition of a silicon germanium film Si_{1-z}Ge_{z} onto a third substrate. From Equation 21, the ratio of the flow rates of the third reaction is

$$\frac{{F}_{3 Si}}{{F}_{3 Gm}} = {( \frac{1 - z}{z} )}^{2} {d}_{3} m ( {T}_{3} ) \qquad ( 36 )$$

The term m{T₃} is given by Equation 29. The constant A can be substituted from Equations 34 or 35. If A is taken from Equation 34, the flow rate ratio is expressed as

$$\frac{{F}_{3 Si}}{{F}_{3 Gm}} = {( \frac{1 - z}{z} )}^{2} ( \frac{{d}_{2} {m}_{1} {ⅇ}^{\frac{E}{{RT}_{1}}}}{{ⅇ}^{\frac{E}{{RT}_{3}}}} ) \qquad ( 37 )$$

The term m₁ can be substituted according to Equation 25 to yield

$$\frac{{F}_{3 Si}}{{F}_{3 Gm}} = {( \frac{1 - z}{z} )}^{2} {( \frac{x}{1 - x} )}^{2} ( \frac{{F}_{1 Si}}{{F}_{1 Gm}} ) ( \frac{{d}_{3}}{{d}_{1}} ) {ⅇ}^{( \frac{E}{R} ) ( \frac{1}{{T}_{1}} - \frac{1}{{T}_{3}} )} \qquad ( 38 )$$

If the constant A is alternatively taken from Equation 35, the ratio of flow rates can be expressed as

$$\frac{{F}_{3 Si}}{{F}_{3 Gm}} = {( \frac{1 - z}{z} )}^{2} {( \frac{y}{1 - y} )}^{2} ( \frac{{F}_{2 Si}}{{F}_{2 Gm}} ) ( \frac{{d}_{3}}{{d}_{2}} ) {ⅇ}^{( \frac{E}{R} ) ( \frac{1}{{T}_{2}} - \frac{1}{{T}_{3}} )} \qquad ( 39 )$$

It will be appreciated that Equations 38 and 39 are mathematically equivalent. If the terms F_{1Gm}, F_{2Gm}, and F_{3Gm} are rewritten in terms of the germane gas flow rates (F_{1Ge}/d₁, F_{2Ge}/d₂, F_{3Ge}/d₃, respectively), then Equations 38 and 39 can be rewritten as

$$\begin{matrix}\frac{{F}_{3 Si}}{{F}_{3 Ge}} = {( \frac{1 - z}{z} )}^{2} {( \frac{x}{1 - x} )}^{2} ( \frac{{F}_{1 Si}}{{F}_{1 Ge}} ) {ⅇ}^{( \frac{E}{R} ) ( \frac{1}{{T}_{1}} - \frac{1}{{T}_{3}} )} & ( 40 ) \\ \frac{{F}_{3 Si}}{{F}_{3 Ge}} = {( \frac{1 - z}{z} )}^{2} {( \frac{y}{1 - y} )}^{2} ( \frac{{F}_{2 Si}}{{F}_{2 Ge}} ) {ⅇ}^{( \frac{E}{R} ) ( \frac{1}{{T}_{2}} - \frac{1}{{T}_{3}} )} & ( 41 )\end{matrix}$$

It will be appreciated that Equations 40 and 41 are mathematically equivalent.

The ratio E/R is given by Equation 33. By substituting the values of m₁ and m₂ from Equation 25, Equation 33 can be rewritten as follows:

$$\frac{E}{R} = \frac{ln [ {( \frac{1 - x}{x} )}^{2} {( \frac{y}{1 - y} )}^{2} ( \frac{{F}_{1 Gm}}{{F}_{1 Si}} ) ( \frac{{F}_{2 Si}}{{F}_{2 Gm}} ) ( \frac{{d}_{1}}{{d}_{2}} ) ]}{\frac{1}{{T}_{1}} - \frac{1}{{T}_{2}}} \qquad ( 42 )$$

If the terms F_{1Gm} and F_{2Gm} are rewritten in terms of the germane gas flow rates (F_{1Ge}/d₁ and F_{2Ge}/d2 respectively), then Equation 42 can be rewritten as

$$\frac{E}{R} = \frac{ln [ {( \frac{1 - x}{x} )}^{2} {( \frac{y}{1 - y} )}^{2} ( \frac{{F}_{1 Ge}}{{F}_{1 Si}} ) ( \frac{{F}_{2 Si}}{{F}_{2 Ge}} ) ]}{\frac{1}{{T}_{1}} - \frac{1}{{T}_{2}}} \qquad ( 43 )$$

Prior to conducting the third reaction, the process engineer can select values for three of the four parameters F_{3Si}, F_{3Gm}, T₃, and z (it is assumed that the dilution rating d₃ is also known). Then, Equations 38 (or 39) and 42 can be used to calculate the value of the unselected parameter. Alternatively, Equations 40, 41, and 43 can be used if the germane flow rates (as opposed to the flow rates of the germane/carrier mixture) are known and/or desired to be calculated. Several examples are presented below for a better understanding of the methods for calculating these parameters.

This method has been conducted in a temperature limited regime where the crystal growth is affected mostly by surface effects. This shows that it is independent of the actual silicon and germanium precursors. Some embodiments of the invention are not limited to hydride precursors, such as SiₙH₂ₙ₊₂ and GeₘH₂ₘ₊₂. For example, this method can be used with chlorinated precursors.

Note that it is possible to deposit the first layer Si₁₋ₓGeₓ and second layer Si_{1-y}Ge_{y} on the same wafer, and then remove the wafer for analysis of the deposited layers in order to set process conditions for depositing the third layer Si_{1-z}Ge_{z} on any wafer, including the same wafer if desired.

Effect of Additional Substances

Equation 13 is a model of the CVD growth of Si₁₋ₓGeₓ from the reaction of silane with germane. Equation 13 can be expressed more generally as

$${( \frac{x}{1 - x} )}^{w} = m ( \frac{{F}_{Ge}}{{F}_{Si}} ) \qquad ( 44 )$$

The value of w has been found to be approximately equal to 2 when the only reactants are silane and germane. In reality, w has been found to vary slightly depending upon total pressure and the flow rates of the precursors. Nevertheless, the assumption that w equals 2 provides a very good approximation of the relationship between the germanium concentration x, the flow rate F_{Ge}, and the flow rate F_{Si}.

Vaporized HCl can be injected in combination with the silane and germane to achieve a tuned₁ selective etching process in which the HCl etches SiGe that deposits on oxide layers while SiGe grows more rapidly on other surfaces. The inventors have discovered that the presence of HCl vapor along with the silane and germane does not change the value of w in Equation 44 (i.e., w remains approximately equal to 2), except for lower pressures. For example, w has been found to be approximately equal to 1 for reactions of HCl, SiH₄, and GeH₄ at 10 Torr, which is at the lower end of the RP CVD (reduced pressure chemical vapor deposition) pressure range of operation. A pressure of 10 Torr is between the RP CVD and the UHVCVD operation pressures. It may be that at 10 Torr the silane chemistry keeps some of its UHVCVD characteristics. However, at a pressure of 80 Torr for the reaction without HCl, the value of w has been found to be about 2.

Dopant materials can be injected in combination with the silane and germane gases for electrical conductivity. One common dopant is diborane, B₂H₆. The inventors have discovered that the presence of small amounts of diborane vapor along with the silane and germane does not change the value of w in Equation 44 (i.e., w remains approximately equal to 2). However, if large amounts of diborane vapor are injected with the silane and germane, then w has been found to be approximately equal to 1. On the other hand, if some HCl vapor is present along with the diborane, silane, and germane, then w has been found to be approximately equal to 2.

### EXAMPLE 1

Suppose a first reaction of gas precursors SiH₄ and GeH₄ takes place within a reaction chamber at a pressure P and temperature T within the kinetic regime associated with the precursors. The SiH₄ gas is injected at a flow rate of 20 sccm (F_{1Si}). The GeH₄ gas source contains a mixture of GeH₄ and H₂ at a dilution of 1.5% (d₁), which is injected at a flow rate of 100 sccm (F_{1Gm}). In addition to the SiH₄ gas and the GeH₄/H₂ mixture, a separate H₂ carrier gas is injected. The precursor gases react to grow a silicon germanium film Si₁₋ₓGeₓ onto a first substrate. The germanium concentration x of the silicon germanium film is then measured as 0.235, or 23.5%.

Now suppose that a second reaction is to take place at the same pressure P and temperature T to deposit a silicon germanium film Si_{1-y}Ge_{y} onto a second substrate. The process engineer wishes to inject SiH₄ gas at a flow rate of 20 sccm (F_{2Si}) and target a germanium concentration y of 12%. Equation 27 can be used to compute the appropriate flow rate F_{2Gm} of a GeH₄ gas source with dilution (d₂) of 1.5% (in many cases, the second reaction will employ the same germane gas source as the first reaction, in which case the dilution ratings d₁ and d₂ are the same) to achieve the targeted germanium concentration. In this case, the required flow rate F_{2Gm} of the monogermane mixture is calculated as 19.7 sccm.

### EXAMPLE 2

After the first reaction described in Example 1, suppose the second reaction will involve the injection of a GeH₄/H₂ mixture with dilution 1.5% (d₂) at a flow rate of 300 sccm (F_{2Gm}), at the same temperature T and overall pressure P. Suppose further that the second reaction is to target a germanium concentration y of 15%. From Equation 27, the appropriate monosilane flow rate F_{2Si} is 181.8 sccm.

### EXAMPLE 3

After the first reaction described in Example 1, suppose the process engineer wishes to inject the SiH₄ gas and the GeH₄/H₂ mixture at flow rates of 20 sccm (F_{2Si}) and 8 sccm (F_{2Gm}), respectively, wherein the latter has a dilution of 1.5% (d₂). Suppose further that the second reaction at the same temperature T and pressure P. The germanium concentration y in the second silicon germanium film can be calculated directly from Equation 27. However, since Equation 27 is a second order equation for y, it may be easier to first calculate m{T, P} from Equation 25, and then calculate y from Equation 22. It will be appreciated that Equations 22 and 25 are mathematically equivalent to Equation 27. Note that since the two reactions are conducted at the same temperature and pressure, the value of m is the same for both reactions. Using Equation 25, m is computed as 1.2582. Then, using Equation 22, the resultant germanium concentration y is calculated as 7.99%. The same value can be computed directly from Equation 27.

The calculation of m from Equation 25 depends on the measured germanium concentration x. It also assumes that the flow rates of the precursors are constant. The value of m can be more accurately determined by conducting a number of different reactions at the temperature T₁ and pressure P₁, measuring the germanium concentration for each deposited silicon germanium film, calculating the value of m for each reaction, and then averaging the calculated values of m for the different reactions. It will be appreciated that m can be more accurately determined as the number of reactions increases.

### EXAMPLE 4

Suppose a first reaction of gas precursors SiH₄ and GeH₄ takes place within a reaction chamber at a pressure P and temperature of 600° C., which is 873.15 K (T₁). The SiH₄ gas is injected at a flow rate of 20 sccm (F_{1Si}). The GeH₄ gas is injected as a mixture of GeH₄ and H₂ with a dilution rating of 1.5% (d₁). The flow rate of the mixture is 50 sccm (F_{1Gm}). In addition, a separate H₂ carrier gas is also injected. The precursors react to form a silicon germanium film Si₁₋ₓGeₓ onto a first substrate. The germanium concentration x of the silicon germanium film is then measured as 0.185, or 18.5%.

Suppose further that a second reaction of the same precursors takes place within the reaction chamber at the same pressure P and temperature of 700° C., which is 973.15 K (T₂). The SiH₄ gas is injected at a flow rate of 20 sccm (F_{2Si}). The GeH₄ gas is injected as a mixture of GeH₄ and H₂ with a dilution rating of 1.5% (d₂). The flow rate of the mixture is 51 sccm (F_{2Gm}). In addition, a separate H₂ carrier gas is also injected. The precursors react to form a silicon germanium film Si_{1-y}Ge_{y} onto a second substrate. The germanium concentration y of the silicon germanium film is then measured as 10.5%.

Suppose further that a third reaction is to take place at the same pressure P and a temperature of 625° C. (T₃=898.15 K) to deposit a silicon germanium film Si_{1-z}Ge_{z} onto a third substrate. The process engineer wishes to inject SiH₄ at a flow rate of 20 sccm (F_{3Si}) and to target a germanium concentration z of 25%. The monogermane gas source has a dilution rating of 1.5% (d₃). Using Equations 38 (or 39) and 42, the appropriate flow rate F_{3Gm} of the GeH₄ mixture is 155.0 sccm.

### EXAMPLE 5

After the first two reactions described in Example 4, suppose a third reaction is to take place at the same pressure P and a temperature of 650° C. (T₃=923.15 K) to deposit a silicon germanium film Si_{1-z}Ge_{z} onto a third substrate. The process engineer wishes to inject a GeH₄/H₂ mixture with dilution 1.5% (d₃) at a flow rate of 125 sccm (F_{3Gm}) and to target a germanium concentration z of 20%. Using Equations 38 (or 39) and 42, the appropriate flow rate F_{3Si} of the SiH₄ precursor is 20.3 sccm.

### EXAMPLE 6

After the first two reactions described in Example 4, suppose a third reaction is to take place at the same pressure P and a temperature of 625° C. (T₃=898.15 K) to deposit a silicon germanium film Si_{1-z}Ge_{z} onto a third substrate. The process engineer wishes to inject the SiH₄ gas at a flow rate of 20 sccm (F_{3Si}) and the GeH₄/H₂ mixture at a flow rate of 12 sccm (F_{3Gm}). The GeH₄/H₂ mixture has a dilution of 1.5% (d₃). Equations 38 (or 39) and 42 can be used to calculate the resultant germanium concentration z, which can subsequently be verified by measurement. However, since Equation 38 (or 39) is a second order equation for z, it may be easier to (1) calculate the ratio E/R from Equation 42, (2) calculate m₁ from Equation 25, (3) calculate the constant A from Equation 34, (4) calculate m₃ from Equation 29, and (5) calculate the germanium concentration z from Equation 22. In this case, the calculated germanium concentration z is 8.49%. It will be appreciated that, in this sequence of steps, the constant A can alternatively be calculated from Equation 35, with m₂ being calculated from Equation 25.

Although the invention has been disclosed in the context of certain embodiments and examples, it will be understood by those skilled in the art that the invention extends beyond the specifically disclosed embodiments to other alternative embodiments and/or uses and obvious modifications and equivalents thereof. Accordingly, the invention is not intended to be limited by the specific disclosures of preferred embodiments herein.

What is claimed is:

1. A method of depositing a silicon germanium layer with a targeted composition onto a substrate, comprising:
injecting a silicon-containing precursor gas at a flow rate F_{1Si} and a germanium-containing precursor gas at a flow rate F_{1Ge} into a reaction chamber toward a substrate at a selected processing temperature with the chamber at a selected processing pressure, the precursor gases reacting to deposit a first silicon germanium layer with composition Si₁₋ₓGeₓ onto the substrate;
measuring x;
injecting a silicon-containing precursor gas at a flow rate F_{2Si} and a germanium-containing precursor gas at a flow rate F_{2Ge} into the reaction chamber toward a substrate at the selected processing temperature with the chamber at the selected processing pressure, the precursor gases reacting to deposit a second silicon germanium layer with composition Si_{1-y}Ge_{y} onto the substrate, wherein y is a targeted value, the ratio F_{2Si}/F_{2Ge} substantially satisfying the equation
$$\frac{{F}_{2 Si}}{{F}_{2 Ge}} = {( \frac{x}{1 - x} )}^{2} {( \frac{1 - y}{y} )}^{2} ( \frac{{F}_{1 Si}}{{F}_{1 Ge}} ) .$$

2. The method of claim 1, wherein the silicon-containing precursor gases comprise silane gas with molecular formula SiₙH₂ₙ₊₂ and the germanium-containing precursor gases comprise germane gas with molecular formula GeₘH₂ₘ₊₂, wherein n and m are whole numbers.

3. The method of claim 1, wherein each of the injecting steps includes injecting a chlorinated precursor into the reaction chamber toward the substrate along with the silicon-containing and germanium-containing precursor gases.

4. The method of claim 2, wherein injecting germane gas comprises injecting a mixture of germane gas and a carrier gas.

5. The method of claim 1, wherein the first and second silicon germanium layers are deposited onto first and second substrates, respectively.

6. The method of claim 1, wherein n equals 1.

7. The method of claim 1, wherein n equals 2.

8. The method of claim 1, wherein n equals 3.

9. The method of claim 1, wherein m equals 1.

10. The method of claim 1, wherein m equals 2.

11. The method of claim 1, wherein m equals 3.

12. A method of depositing a silicon germanium layer with a targeted composition onto a substrate, comprising:
providing a first substrate at a selected processing temperature in a reaction chamber at a selected processing pressure;
injecting SiH₄ gas at a flow rate F_{1Si} and GeH₄ gas at a flow rate F_{1Ge} into the reaction chamber toward the first substrate, the SiH₄ and GeH₄ gases reacting to deposit silicon germanium with composition Si₁₋ₓGeₓ onto the first substrate;
measuring x;
providing a second substrate at the selected processing temperature in the reaction chamber at the selected processing pressure; and
injecting SiH₄ gas at a flow rate F_{2Si} and GeH₄ gas at a flow rate F_{2Ge} into the reaction chamber toward the second substrate, the ratio F_{2Si}/F_{2Ge} substantially satisfying the equation
$$\frac{{F}_{2 Si}}{{F}_{2 Gm}} = {( \frac{x}{1 - x} )}^{2} {( \frac{1 - y}{y} )}^{2} ( \frac{{F}_{1 Si}}{{F}_{1 Gm}} ) .$$
wherein y is a targeted value of a composition Si_{1-y}Ge_{y} of a silicon germanium layer deposited onto the second substrate by a reaction of the SiH₄ and GeH₄ gases.

13. A method of calculating a parameter associated with a deposition process of a silicon germanium layer, comprising:
providing a substrate in a reaction chamber;
injecting a silane gas with a molecular formula SiₙH₂ₙ₊₂ at a flow rate F_{1Si} and a mixture of a germane gas and a carrier gas at a flow rate F_{1Gm} into the reaction chamber toward the substrate, the silane and germane gases reacting to deposit silicon germanium with composition Si₁₋ₓGeₓ onto the substrate, the germane gas having a molecular formula GeₘH₂ₘ₊₂, the mixture having a dilution d₁, wherein n and m are whole numbers;
measuring x;
selecting two parameters from the set comprising (1) a flow rate F_{2Si} of a silane gas with a molecular formula SiₙH₂ₙ₊₂, (2) a flow rate F_{2Gm} of a mixture of a carrier gas and a germane gas with a molecular formula GeₘH₂ₘ₊₂ and dilution d₂, and (3) a concentration y in a silicon germanium composition Si_{1-y}Ge_{y};
assigning values to the two selected parameters; and
calculating the unselected parameter of said set from the equation
$$\frac{{F}_{2 Si}}{{F}_{2 Gm}} = {( \frac{x}{1 - x} )}^{2} {( \frac{1 - y}{y} )}^{2} ( \frac{{d}_{2}}{{d}_{1}} ) ( \frac{{F}_{1 Si}}{{F}_{1 Gm}} )$$
or from one or more equations that are collectively mathematically equivalent to the above equation.

14. The method of claim 13, wherein n and m are equal to 1.

15. The method of claim 13, further comprising performing at least one action from the set comprising (1) storing the calculated parameter in a storage, (2) displaying the calculated parameter, and (3) using the calculated parameter as a process parameter in depositing a silicon germanium layer with composition Si_{1-y}Ge_{y} onto a substrate.

16. A method of depositing a silicon germanium film with a targeted composition onto a substrate, comprising:
injecting SiH₄ gas at a flow rate F_{1Si} and GeH₄ gas at a flow rate F_{1Ge} into the reaction chamber toward a substrate at a first temperature T₁ (in Kelvin), the SiH₄ and GeH₄ gases reacting to deposit a first silicon germanium film with composition Si₁₋ₓGeₓ onto the substrate;
measuring x;
injecting SiH₄ gas at a flow rate F_{2Si} and GeH₄ gas at a flow rate F_{2Ge} into the reaction chamber toward a substrate at a second temperature T₂ (in Kelvin), the SiH₄ and GeH₄ gases reacting to deposit a second silicon germanium film with composition Si_{1-y}Ge_{y} onto the substrate;
measuring y;
injecting SiH₄ gas at a flow rate F_{3Si} and GeH₄ gas at a flow rate F_{3Ge} into the reaction chamber toward a substrate at a third temperature T3 (in Kelvin), the ratio F_{3Si}/F_{3Ge} substantially satisfying the equation
$$\frac{{F}_{3 Si}}{{F}_{3 Ge}} = {( \frac{1 - z}{z} )}^{2} {( \frac{x}{1 - x} )}^{2} ( \frac{{F}_{1 Si}}{{F}_{1 Ge}} ) {ⅇ}^{( \frac{E}{R} ) ( \frac{1}{{T}_{1}} - \frac{1}{{T}_{3}} )}$$
wherein z is a targeted value of a composition Si_{1-z}Ge_{z} of a third silicon germanium film deposited onto a substrate at a temperature T₃ (in Kelvin) by a reaction of SiH₄ and GeH₄ gases, wherein
$$\frac{E}{R} = \frac{ln [ {( \frac{1 - x}{x} )}^{2} {( \frac{y}{1 - y} )}^{2} ( \frac{{F}_{1 Ge}}{{F}_{1 Si}} ) ( \frac{{F}_{2 Si}}{{F}_{2 Ge}} ) ]}{\frac{1}{{T}_{1}} - \frac{1}{{T}_{2}}} .$$

17. The method of claim 16, wherein the first, second, and third silicon germanium films are deposited onto first, second₁ and third substrates, respectively.

18. A method of calculating a parameter associated with a deposition process of a silicon germanium film, comprising:
injecting silane gas at a flow rate F_{1Si} and a mixture of a carrier gas and germane gas with a dilution d₁ at a flow rate F_{1Gm} into a reaction chamber toward a substrate at a first temperature T₁ (in Kelvin), the silane and germane gases reacting to deposit a first silicon germanium film with composition Si₁₋ₓGeₓ onto the substrate, the silane and germane gases having molecular formulas SiₙH₂ₙ₊₂ and GeₘH₂ₘ₊₂, respectively, wherein n and m are whole numbers;
measuring x;
injecting silane gas with a molecular formula SiₙH₂ₙ₊₂ at a flow rate F_{2Si} and a mixture of a carrier gas and germane gas with a dilution d₂ at a flow rate F_{2Gm} into the reaction chamber toward a substrate at a second temperature T₂ (in Kelvin), the silane and germane gases reacting to deposit a second silicon germanium film with composition Si_{1-y}Ge_{y} onto the substrate, the germane gas having a molecular formula GeₘH₂ₘ₊₂;
measuring y;
selecting three parameters from the set comprising (1) a flow rate F_{3Si} of a silane gas with a molecular formula SiₙH₂ₙ₊₂, (2) a flow rate F_{3Gm} of a mixture of a carrier gas and germane gas with a dilution d₃, the germane gas having a molecular formula GeₘH₂ₘ₊₂, (3) a temperature T₃ (in Kelvin), and (4) a concentration z in a silicon germanium composition Si_{1-z}Ge_{z};
assigning values to the three selected parameters; and
calculating the unselected parameter of said set from one of the two equations
$$\frac{{F}_{3 Si}}{{F}_{3 Gm}} = {( \frac{1 - z}{z} )}^{2} {( \frac{x}{1 - x} )}^{2} ( \frac{{F}_{1 Si}}{{F}_{1 Gm}} ) ( \frac{{d}_{3}}{{d}_{1}} ) {ⅇ}^{( \frac{E}{R} ) ( \frac{1}{{T}_{1}} - \frac{1}{{T}_{3}} )}$$
$$and$$
$$\frac{{F}_{3 Si}}{{F}_{3 Gm}} = {( \frac{1 - z}{z} )}^{2} {( \frac{y}{1 - y} )}^{2} ( \frac{{F}_{2 Si}}{{F}_{2 Gm}} ) ( \frac{{d}_{3}}{{d}_{2}} ) {ⅇ}^{( \frac{E}{R} ) ( \frac{1}{{T}_{2}} - \frac{1}{{T}_{3}} )}$$
or from one or more equations that are collectively mathematically equivalent to either of the above equations, wherein
$$\frac{E}{R} \frac{ln [ {( \frac{1 - x}{x} )}^{2} {( \frac{y}{1 - y} )}^{2} ( \frac{{F}_{1 Gm}}{{F}_{1 Si}} ) ( \frac{{F}_{2 Si}}{{F}_{2 Gm}} ) ( \frac{{d}_{1}}{{d}_{2}} ) ]}{\frac{1}{{T}_{1}} - \frac{1}{{T}_{2}}} .$$

19. The method of claim 18, wherein n and m are equal to 1.

20. The method of claim 19, further comprising performing at least one action from the set comprising (1) storing the calculated parameter in a storage, (2) displaying the calculated parameter, and (3) using the calculated parameter as a process parameter in depositing a third silicon germanium film with composition Si_{1-y}Ge_{y} onto a substrate.

21. An apparatus for depositing a silicon germanium layer with a targeted composition onto a substrate, comprising:
a reaction chamber containing a substrate support structure;
a source of a silicon-containing precursor gas;
a source of a germanium-containing precursor gas;
an injector assembly connected to the gas sources for injecting the silicon-containing and germanium-containing gases at controllable flow rates into the reaction chamber toward a substrate supported by the substrate support structure; and
a computer unit configured to store information associated with a first reaction of the silicon-containing precursor gas injected into the chamber at a flow rate F_{1Si} and the germanium-containing precursor gas injected into the chamber at a flow rate F_{1Ge} by the injector assembly to deposit a first silicon germanium layer with composition Si₁₋ₓGeₓ onto a substrate supported by the substrate support structure, the stored information from the first reaction comprising F_{1Si}, F_{1Ge}, and x, the computer unit also configured to store information associated with a second reaction of a silicon-containing precursor gas at a flow rate F_{2Si} and a germanium-containing precursor gas at a flow rate F_{2Ge} to deposit a second silicon germanium layer with composition Si_{1-y}Ge_{y}, the stored information from the second reaction comprising only two parameters of the set consisting of F_{2Si}, F_{2Ge}, and y;
wherein the computer unit is additionally configured to calculate the unstored parameter of the set consisting of F_{2Si}, F_{2Ge}, and y from the equation
$$\frac{{F}_{2 Si}}{{F}_{2 Ge}} = {( \frac{x}{1 - x} )}^{2} {( \frac{1 - y}{y} )}^{2} ( \frac{{F}_{1 Si}}{{F}_{1 Ge}} ) .$$

22. The apparatus of claim 21, wherein the silicon-containing precursor gas comprises silane gas with molecular formula SiₙH₂ₙ₊₂ and the germanium-containing precursor gas comprises germane gas with molecular formula GeₘH₂ₘ₊₂, wherein n and m are whole numbers.

23. The apparatus of claim 21, further comprising a source of a chlorinated precursor gas connected to the injector assembly for injecting the chlorinated precursor gas into the reaction chamber toward a substrate supported by the substrate support structure.

24. The apparatus of claim 21, wherein the computer unit is configured to control the injector assembly to inject the silicon-containing and germanium-containing gases into the reaction chamber substantially at the flow rates F_{2Si} and F_{2Ge}, respectively, toward a substrate supported by the substrate support structure.

25. An apparatus for depositing a silicon germanium layer with a targeted composition onto a substrate, comprising:
a reaction chamber containing a substrate support structure;
a source of SiH₄ gas;
a source of GeH₄ gas;
an injector assembly connected to the SiH₄ and GeH₄ gas sources for injecting SiH₄ gas and GeH₄ gas at controllable flow rates into the reaction chamber toward a substrate supported by the substrate support structure; and
a computer unit configured to store information associated with a first reaction of SiH₄ gas injected into the chamber at a flow rate F_{1Si} and GeH₄ gas injected into the chamber at a flow rate F_{1Ge} by the injector assembly to deposit a first silicon germanium layer with composition Si₁₋ₓGeₓ onto a first substrate supported by the substrate support structure, the stored information from the first reaction comprising F_{1Si}, F_{1Ge}, and x, the computer unit also configured to store information associated with a second reaction of SiH₄ gas at a flow rate F_{2Si} and GeH₄ gas at a flow rate F_{2Ge} to deposit a second silicon germanium layer with composition Si_{1-y}Ge_{y}, the stored information from the second reaction comprising only two parameters of the set consisting of F_{2Si}, F_{2Ge}, and y;
wherein the computer unit is additionally configured to calculate the unstored parameter of the set consisting of F_{2Si}, F_{2Ge}, and y from the equation
$$\frac{{F}_{2 Si}}{{F}_{2 Ge}} = {( \frac{x}{1 - x} )}^{2} {( \frac{1 - y}{y} )}^{2} ( \frac{{F}_{1 Si}}{{F}_{1 Ge}} ) .$$

26. The apparatus of claim 25, wherein the computer unit is configured to control the injector assembly to inject the SiH₄ and GeH₄ gases into the reaction chamber substantially at the flow rates F_{2Si} and F_{2Ge}, respectively, toward a substrate supported by the substrate support structure.

27. An apparatus for calculating a parameter associated with a deposition process of a silicon germanium layer, comprising:
a reaction chamber containing a substrate support structure;
a source of silane gas having a molecular formula SiₙH₂ₙ₊₂, wherein n is a whole number;
a source of a mixture of a carrier gas and a germane gas with a dilution d₁, the germane gas having a molecular formula GeₘH₂ₘ₊₂, wherein m is a whole number;
an injector assembly connected to the gas sources for injecting the silane gas and the mixture of carrier and germane gas at controllable flow rates into the reaction chamber toward a substrate supported by the substrate support structure; and
a control system configured to store information associated with a reaction of the silane gas injected into the chamber at a flow rate F_{1Si} and the carrier/germane gas mixture injected into the chamber at a flow rate F_{1Gm} by the injector assembly to deposit a silicon germanium layer with composition Si₁₋ₓGeₓ onto a substrate supported by the substrate support structure, the stored information comprising F_{1Si}, F_{1Gm}, and x;
wherein the control system is additionally configured to store assigned values of two selected parameters from the set comprising (1) a flow rate F_{2Si} of a silane gas with a molecular formula SiₙH₂ₙ₊₂, (2) a flow rate F_{2Gm} of a mixture of a carrier gas and a germane gas with a molecular formula GeₘH₂ₘ₊₂ and dilution d₂, and (3) a concentration y in a silicon germanium composition Si_{1-y}Ge_{y}, the control system configured to calculate the unselected parameter of said set from the equation
$$\frac{{F}_{2 Si}}{{F}_{2 Gm}} = {( \frac{x}{1 - x} )}^{2} {( \frac{1 - y}{y} )}^{2} ( \frac{{d}_{2}}{{d}_{1}} ) ( \frac{{F}_{1 Si}}{{F}_{1 Gm}} )$$
or from one or more equations that are collectively mathematically equivalent to the above equation.

28. The apparatus of claim 27, wherein n and m are equal to 1.

29. The apparatus of claim 27, wherein the control system is configured to perform at least one action from the set comprising (1) storing the calculated parameter in a storage, (2) displaying the calculated parameter, and (3) using the calculated parameter as a process parameter in depositing a silicon germanium layer with composition Si_{1-y}Ge_{y} onto a substrate.

30. An apparatus for depositing a silicon germanium layer with a targeted composition onto a substrate, comprising:
a reaction chamber containing a substrate support structure;
a source of silane gas with a molecular formula SiₙH₂ₙ₊₂, wherein n is a whole number;
a source of germane gas with a molecular formula GeₘH₂ₘ₊₂, wherein m is a whole number;
a gas injector assembly connected to the gas sources for injecting the silane and germane gases at controllable flow rates into the reaction chamber toward a substrate supported by the substrate support structure;
a control system configured to store information associated with a first reaction of the silane gas injected into the chamber at a flow rate F_{1Si} and the germane gas injected into the chamber at a flow rate F_{1Ge} by the gas injector assembly to deposit a first silicon germanium layer with composition Si₁₋ₓGeₓ onto a substrate supported by the substrate support structure at a first substrate temperature T₁ (in Kelvin), the control system also configured to store information associated with a second reaction of the silane gas injected into the chamber at a flow rate F_{2Si} and the germane gas injected into the chamber at a flow rate F_{2Ge} by the gas injector assembly to deposit a second silicon germanium layer with composition Si_{1-y}Ge_{y} onto a substrate supported by the substrate support structure at a second substrate temperature T₂ (in Kelvin), the stored information of the first and second reactions comprising F_{1Si}, F_{1Ge}, T₁, x, F_{2Si}, F_{2Ge}, T₂, and y, the control system being configured to store information associated with a third reaction of silane gas at a flow rate F_{3Si} and germane gas at flow rate F_{3Ge} to deposit a third silicon germanium layer with composition Si_{1-z}Ge_{z} onto a substrate at a third substrate temperature T₃ (in Kelvin), the stored information of the third reaction comprising only two parameters of the set consisting of F_{3Si}, F_{3Ge}, and z;
wherein the control system is additionally configured to calculate the unstored parameter of the set consisting of F_{3Si}, F_{3Ge}, and z from the equations
$$\frac{{F}_{3 Si}}{{F}_{3 Ge}} = {( \frac{1 - z}{z} )}^{2} {( \frac{x}{1 - x} )}^{2} ( \frac{{F}_{1 Si}}{{F}_{1 Ge}} ) {ⅇ}^{( \frac{E}{R} ) ( \frac{1}{{T}_{1}} - \frac{1}{{T}_{3}} )}$$
$$and$$
$$\frac{E}{R} = \frac{ln [ {( \frac{1 - x}{x} )}^{2} {( \frac{y}{1 - y} )}^{2} ( \frac{{F}_{1 Ge}}{{F}_{1 Si}} ) ( \frac{{F}_{2 Si}}{{F}_{2 Ge}} ) ]}{\frac{1}{{T}_{1}} - \frac{1}{{T}_{2}}} .$$

31. The apparatus of claim 30, wherein the control system is configured to control the gas injector assembly to inject the silane and germane gases substantially at the flow rates F_{3Si} and F_{3Ge}, respectively, toward a substrate supported by the substrate support structure at the third substrate temperature T₃.

32. The apparatus of claim 30, wherein n equals 1.

33. The apparatus of claim 30, wherein n equals 2.

34. The apparatus of claim 30, wherein n equals 3.

35. The apparatus of claim 30, wherein m equals 1.

36. The apparatus of claim 30, wherein m equals 2.

37. The apparatus of claim 30, wherein m equals 3.

38. The apparatus of claim 30, wherein the control system is configured to store the information for a case in which the first silicon germanium layer is deposited onto a first substrate and the second silicon germanium layer is deposited onto a second substrate, the control system being configured to control the gas injector assembly to deposit the third silicon germanium layer onto a third substrate.

39. The apparatus of claim 38, wherein n and m equal 1.

40. An apparatus for calculating a parameter associated with a deposition process of a silicon germanium film, comprising:
a reaction chamber containing a substrate support structure;
a source of silane gas having a molecular formula SiₙH₂ₙ₊₂, wherein n is a whole number;
a source of a mixture of a carrier gas and germane gas with a dilution d, the germane gas having a molecular formula GeₘH₂ₘ₊₂, wherein m is a whole number;
a gas injector assembly connected to the gas sources for injecting the silane gas and the carrier/germane gas mixture at controllable flow rates into the reaction chamber toward a substrate supported by the substrate support structure;
a control system configured to store information associated with a first reaction of the silane gas injected into the chamber at a flow rate F_{1Si} and the carrier/germane gas mixture injected into the chamber at a flow rate F_{1Gm} by the gas injector assembly to deposit a silicon germanium film with composition Si₁₋ₓGeₓ onto a substrate supported by the substrate support structure at a first substrate temperature T₁, the control system also configured to store information associated with a second reaction of the silane gas injected into the chamber at a flow rate F_{2Si} and the carrier/germane gas mixture injected into the chamber at a flow rate F_{2Gm} by the gas injector assembly to deposit a silicon germanium film with composition Si_{1-y}Ge_{y} onto a substrate supported by the substrate support structure at a second substrate temperature T₂, the stored information comprising F_{1Si}, F_{1Gm}, T₁, x, F_{2Si}, F_{2Gm}, T₂, and y;
wherein the control system is additionally configured to store assigned values of three selected parameters from the set comprising (1) a flow rate F_{3Si} of silane gas with a molecular formula SiₙH₂ₙ₊₂, (2) a flow rate F_{3Gm} of a mixture of a carrier gas and germane gas with a dilution d₃, the germane gas having a molecular formula GeₘH₂ₘ₊₂, (3) a temperature T₃ (in Kelvin), and (4) a concentration z in a silicon germanium composition Si_{1-z}Ge_{z}, the control system configured to calculate the unselected parameter of said set from one of the two equations
$$\frac{{F}_{3 Si}}{{F}_{3 Gm}} = {( \frac{1 - z}{z} )}^{2} {( \frac{x}{1 - x} )}^{2} ( \frac{{F}_{1 Si}}{{F}_{1 Gm}} ) ( \frac{{d}_{3}}{d} ) {ⅇ}^{( \frac{E}{R} ) ( \frac{1}{{T}_{1}} - \frac{1}{{T}_{3}} )}$$
$$and$$
$$\frac{{F}_{3 Si}}{{F}_{3 Gm}} = {( \frac{1 - z}{z} )}^{2} {( \frac{y}{1 - y} )}^{2} ( \frac{{F}_{2 Si}}{{F}_{2 Gm}} ) ( \frac{{d}_{3}}{d} ) {ⅇ}^{( \frac{E}{R} ) ( \frac{1}{{T}_{2}} - \frac{1}{{T}_{3}} )}$$
or from one or more equations that are collectively mathematically equivalent to either of the above equations, wherein
$$\frac{E}{R} = \frac{ln [ {( \frac{1 - x}{x} )}^{2} {( \frac{y}{1 - y} )}^{2} ( \frac{{F}_{1 Gm}}{{F}_{1 Si}} ) ( \frac{{F}_{2 Si}}{{F}_{2 Gm}} ) ]}{\frac{1}{{T}_{1}} - \frac{1}{{T}_{2}}} .$$

41. The apparatus of claim 40, wherein n and m equal 1.
